(19) United States
(12) Patent Application Publication
(10) Pub. No.: US 2023/0357283 A1
(43) Pub. Date: Nov. 9, 2023

(54) ORGANIC PHOTOELECTRIC DEVICE, IMAGE SENSOR, AND ELECTRONIC DEVICE COMPRISING THE IMAGE SENSOR

(71) Applicant: SAMSUNG ELECTRONICS CO., LTD., Suwon-si (KR)

(72) Inventors: Yoshiaki OBANA, Suwon-si (KR); Hyeyun PARK, Suwon-si (KR); Sujin KWON, Suwon-si (KR); Shiyong YI, Suwon-si (KR); Junwon HAN, Suwon-si (KR); Hiroshi MORITA, Tokyo (JP); Rieko HAMADA, Tokyo (JP); Kouji IINO, Tokyo (JP)

(73) Assignee: ADEKA CORPORATION, Tokyo (JP)

(21) Appl. No.: 18/218,206

(22) Filed: Jul. 5, 2023

Related U.S. Application Data
(62) Division of application No. 16/668,588, filed on Oct. 30, 2019.

(30) Foreign Application Priority Data
Oct. 31, 2018 (KR) 10-2018-0132569
Jul. 8, 2019 (KR) 10-2019-0082231

(51) Int. Cl. C07F 5/02; H10K 30/00; H10K 39/32; H10K 85/30; H10K 85/60

(52) U.S. Cl. CPC C07F 5/02; C07F 5/022; H10K 30/451; H10K 39/32; H10K 85/322; H10K 85/655; H10K 85/656; H10K 85/6576

(57) ABSTRACT

An organic compound, an organic photoelectric device, an image sensor, and an electronic device, the organic compound being represented by Chemical Formula 1:

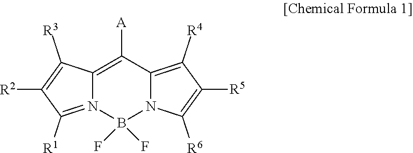

wherein, in Chemical Formula 1, R¹, R², R³, R⁴, R⁵, and R⁶ are each independently a hydrogen atom, a substituted or unsubstituted C1-C4 alkyl group, a substituted or unsubstituted C1-C4 alkoxy group, or a substituted or unsubstituted C1-C4 alkylthio group, and A is a functional group including a heteroaryl group that includes at least one sulfur atom.

### CROSS-REFERENCE TO RELATED APPLICATIONS

This is a divisional application based on pending application Ser. No. 16/668,588, filed Oct. 30, 2019, the entire contents of which is hereby incorporated by reference.

Korean Patent Application No. 10-2018-0132569, filed on Oct. 31, 2018, and Korean Patent Application No. 10-2019-0082231, filed on Jul. 8, 2019, in the Korean Intellectual Property Office, and entitled: “Organic Compound, and Organic Photoelectric Device, Image Sensor, and Electronic Device Including the Organic Compound,” is incorporated by reference herein in its entirety.

### BACKGROUND

### 1. Field

Embodiments relate to an organic compound, and an organic photoelectric device, an image sensor, and an electronic device including the organic compound.

### 2. Description of the Related Art

In order to improve the sensitivity in an image sensor including a photodiode, which is one of the photoelectric devices that converts light into an electric signal by using the photoelectric effect, an organic material capable of selectively absorbing light of a particular wavelength region, as a constituent material of the photodiode instead of silicon has been considered.

### SUMMARY

The embodiments may be realized by providing an organic compound represented by Chemical Formula 1,

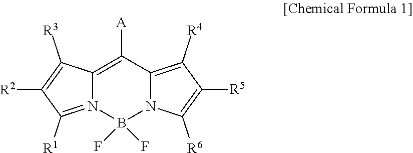

wherein, in Chemical Formula 1, R¹, R², R³, R⁴, R⁵, and R⁶ are each independently a hydrogen atom, a substituted or unsubstituted C1-C4 alkyl group, a substituted or unsubstituted C1-C4 alkoxy group, or a substituted or unsubstituted C1-C4 alkylthio group, and A is a functional group including a heteroaryl group that includes at least one sulfur atom.

The embodiments may be realized by providing an organic compound represented by Chemical Formula 1,

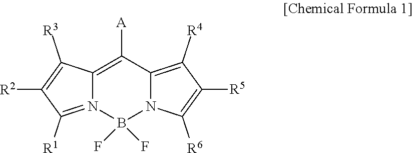

wherein, in Chemical Formula 1, R¹, R², R³, R⁴, R⁵, and R⁶ are each independently a hydrogen atom, a C1-C4 alkyl group, a C1-C4 alkoxy group, or a C1-C4 alkylthio group, and A is a functional group including a 5-membered heterocycle that includes a sulfur atom.

The embodiments may be realized by providing an organic photoelectric device including a first electrode and a second electrode facing each other; and an active layer between the first electrode and the second electrode, wherein the active layer includes an organic compound represented by Chemical Formula 1,

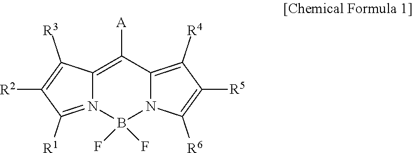

wherein, in Chemical Formula 1, R¹, R², R³, R⁴, R₅, and R⁶ are each independently a hydrogen atom, a substituted or unsubstituted C1-C4 alkyl group, a substituted or unsubstituted C1-C4 alkoxy group, or a substituted or unsubstituted C1-C4 alkylthio group, and A is a functional group including a heteroaryl group that includes at least one sulfur atom.

The embodiments may be realized by providing an image sensor including a semiconductor substrate; and an organic photoelectric device on the semiconductor substrate, wherein the organic photoelectric device includes a first electrode and a second electrode facing each other; and an active layer between the first electrode and the second electrode, the active layer including an organic compound represented by Chemical Formula 1,

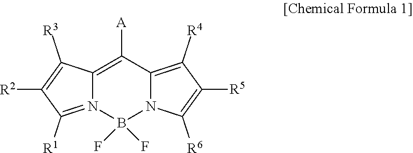

wherein, in Chemical Formula 1, R¹, R², R³, R⁴, R⁵, and R⁶ are each independently a hydrogen atom, a substituted or unsubstituted C1-C4 alkyl group, a substituted or unsubstituted C1-C4 alkoxy group, or a substituted or unsubstituted C1-C4 alkylthio group, and A is a functional group including a heteroaryl group that includes at least one sulfur atom.

### BRIEF DESCRIPTION OF THE DRAWINGS

Features will be apparent to those of skill in the art by describing in detail exemplary embodiments with reference to the attached drawings in which:

FIG. 1 illustrates a cross-sectional view of an organic photoelectric device according to embodiments;

FIG. 2 illustrates a cross-sectional view of an organic photoelectric device according to other embodiments;

FIG. 3 illustrates a diagram of an image sensor according to embodiments;

FIG. 4 illustrates a cross-sectional view of an image sensor according to embodiments;

FIG. 5 illustrates a cross-sectional view of an image sensor according to other embodiments;

FIG. 6 illustrates a cross-sectional view of an image sensor according to other embodiments;

FIG. 7 illustrates a diagram of an image sensor according to other embodiments;

FIG. 8 illustrates an electronic device according to embodiments;

FIG. 9 illustrates an electronic device according to other embodiments;

FIGS. 10A to 10H illustrate absorption curve graphs of absorption properties of compounds according to other embodiments, and FIGS. 10I and 10J illustrate absorption curve graphs of absorption properties of compounds according to comparison examples;

FIG. 11 illustrates a cross-sectional view of examples of manufacturing an organic photoelectric device, according to embodiments; and

FIGS. 12A to 12F illustrate graphs of the results of evaluating the external quantum efficiency (EQE) depending on the wavelength of an organic photoelectric device according to embodiments, and FIG. 12G illustrates a graph of the results of evaluating the EQE depending on the wavelength of an organic photoelectric device according to a comparison example.

### DETAILED DESCRIPTION

An organic compound according to embodiments may be represented by Chemical Formula 1.

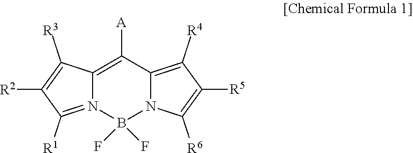

In Chemical Formula 1, R¹, R², R³, R⁴, R⁵, and R⁶ may each independently be or include, e.g., a hydrogen atom, a substituted or unsubstituted C1-C4 linear or branched alkyl group, a substituted or unsubstituted C1-C4 linear or branched alkoxy group, or a substituted or unsubstituted C1-C4 linear or branched alkylthio group. As used herein, the term “or” is not an exclusive term, e.g., “A or B” includes A, B, or A and B. A may be, e.g., a functional group having a heteroaryl group that includes at least one sulfur atom.

The heteroaryl group included in A may include, e.g., a 5-membered ring that includes a sulfur atom (e.g., in the ring). In an implementation, the heteroaryl group including a 5-membered ring may include, e.g., thiophene, thiazole, thiodiazole, benzothiophene, dibenzothiophene, dithiothiophene, benzodithiophene, thienothiophene, or dithienopyrrole.

In an implementation, A may include a C5-C30 substituted or unsubstituted fused polycyclic group. The term “fused polycyclic group” used herein means a substituent including at least two rings in which at least one aromatic ring and/or at least one alicyclic ring are fused together.

In an implementation, A may include at least three ring structures. At least one ring structure of the at least three ring structures may include a thiophene ring (e.g., thiophene moiety).

In an implementation, A may include a fused polycyclic group in which a thiophene ring is fused.

In an implementation, A may include a monocyclic ring moiety or a polycyclic ring moiety, the monocyclic ring moiety or polycyclic ring moiety may include at least one thiophene ring.

In an implementation, a total number of rings included in the organic compound of Chemical Formula 1 may be, e.g., 5 to 8.

In an implementation, A may have a structure represented by Chemical Formula 2.

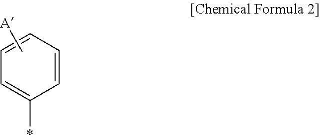

In Chemical Formula 2, A′ may be a functional group having a heteroaryl group including at least one sulfur atom, and “*” may be a bonding position. A′ may include a C5-C30 substituted or unsubstituted fused polycyclic group. A′ may include a monocyclic or polycyclic ring moiety including at least one thiophene ring.

In an implementation, A may have a structure represented by Chemical Formula 3.

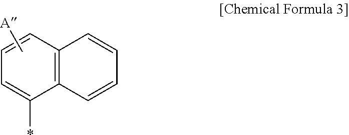

In Chemical Formula 3, A″ may be a functional group having a heteroaryl group including at least one sulfur atom, and “*” may be a bonding position. A″ may include a monocyclic or polycyclic ring moiety including at least one thiophene ring.

In an implementation, A may be, e.g., a group represented by one of the following formulae.

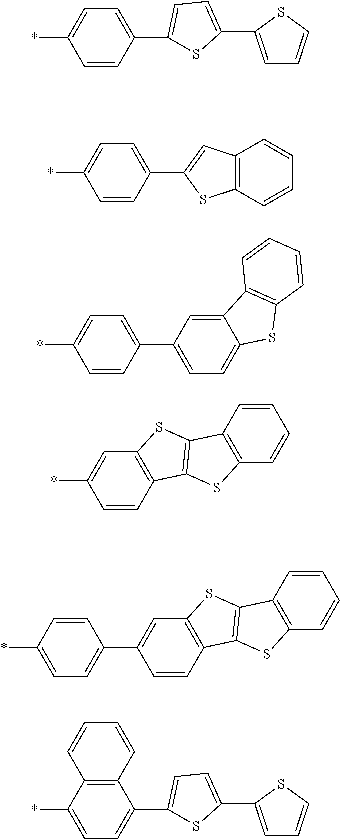

In the above formulae, “*” may be a bonding position. In the above formulae, the bonding position represented by “*” may be connected to the meso position of the BODIPY (boron-dipyrromethene, IUPAC Name: 4,4-difluoro-4-bora-3a,4a-diaza-s-indacene) core of Chemical Formula 1.

In an implementation, in Chemical Formula 1, R¹, R³, R⁴, and R⁶ may each independently be, e.g., a C1-C3 alkyl group, and R² and R⁵ may each independently be, e.g., a hydrogen atom or a C1-C3 alkyl group. In an implementation, R¹, R², R³, R⁴, R⁵, and R⁶ each may not include a ring structure.

The organic compound of Chemical Formula 1 may be a compound that selectively absorbs light in a green wavelength region and may have a maximum absorption wavelength (e.g., wavelength of maximum absorption) λ max of about 530 nm to about 560 nm in a thin film state and may exhibit an absorption curve having a full width at half maximum (FWHM) of about 50 nm to about 100 nm in a thin film state.

Organic compounds according to some embodiments may include fused cyclic thiophene structures having heteroatoms such as sulfur atoms. A fused cyclic thiophene, which is a cyclic compound including a sulfur atom, may include a sulfur atom having a high polarity and having a larger atomic radius than carbon. For example, when an organic compound including a fused cyclic thiophene structure according to some embodiments is processed in the form of a thin film, a sulfur-sulfur bond may be formed between adjacent molecules in the thin film and thus it may have a thin film structure in which molecules are densely packed. Also, in a fused cyclic thiophene structure having sulfur atoms, carrier mobility may be improved by superposition of p orbitals of sulfur atoms having a large atomic radius.

Also, in the fused cyclic thiophene structure, the electrons of a p orbital on an aromatic ring may be widely distributed on a fused cycle with extended planarity instead of existing only in a local region. For example, the binding energy of a carrier existing on the p orbital may be lowered and the intermolecular movement of the carrier may be smooth. When the carrier mobility is improved in an organic photoelectric device, the carrier generated by the absorption of light may be rapidly moved to an opposite electrode and thus quantum efficiency may be improved.

Also, when an organic compound according to embodiments includes a fused cyclic thiophene structure, the thermal stability of the organic compound may be further improved. For example, it may be advantageously applied to an organic photoelectric device manufacturing process including a relatively high-temperature process. When an organic compound according to embodiments includes a fused cyclic thiophene structure, it may be advantageously applied to a process of forming a film by using a deposition process. In an implementation, the compound may be charged into a crucible in a solid state and then heated under vacuum to sublimate the compound, and the sublimated compound may be used to form a thin film on a substrate arranged to face the crucible.

Also, when fused rings have similar molecular weights, because fused aromatic rings are bonded to each other in a plurality of atoms, the fused aromatic ring may tend to be difficult to decompose as compared with an aromatic ring bonded in a single bond. Also, a sulfur atom may be included as a hetero atom included in a fused cyclic ring, and a highest occupied molecular orbital (HOMO) may be stabilized and a decomposition reaction of the compound may be suppressed.

An organic compound according to embodiments may be advantageously applied to organic photoelectric devices such as photodiodes or phototransistors. An organic photoelectric device obtained from an organic compound according to embodiments may provide improved photoelectric conversion efficiency and may maintain stable external quantum efficiency (EQE) characteristics. An organic photoelectric device obtained from an organic compound according to embodiments may be advantageously applied to various devices, e.g., image sensors, solar cells, or organic light-emitting diodes.

Also, an organic compound according to embodiments may selectively absorb light in a green wavelength region and may provide excellent thermal stability and carrier mobility. For example, an organic photoelectric device including an organic compound according to embodiments may exhibit high EQE. Also, an organic compound according to embodiments may be used as a p-type semiconductor compound of an organic photoelectric device used in a complementary metal oxide semiconductor (CMOS) image sensor.

Next, an organic photoelectric device according to embodiments will be described in detail with reference to particular examples.

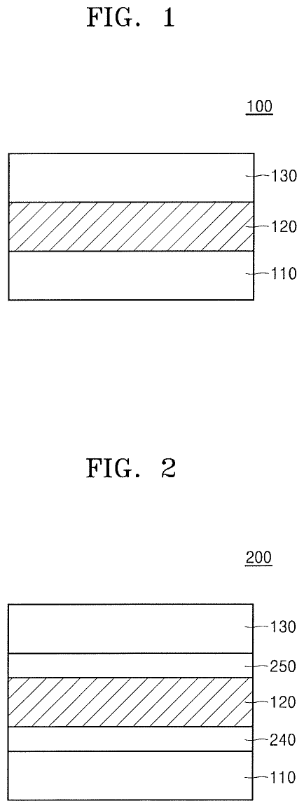

FIG. 1 illustrates a cross-sectional view of an organic photoelectric device according to embodiments.

Referring to FIG. 1, an organic photoelectric device 100 may include a first electrode 110, an active layer 120 on the first electrode 110, and a second electrode 130 on the active layer 120. The first electrode 110 and the second electrode 130 may face each other with the active layer 120 therebetween.

One of the first electrode 110 and the second electrode 130 may be an anode and the other may be a cathode. In an implementation, at least one of the first electrode 110 and the second electrode 130 may be a transparent electrode. The transparent electrode may include a transparent conductor, e.g., indium tin oxide (ITO) or indium zinc oxide (IZO). In an implementation, at least one of the first electrode 110 and the second electrode 130 may include a single-layer or a multi-layer metal thin film. In an implementation, one of the first electrode 110 and the second electrode 130 may be an opaque electrode. The opaque electrode may include aluminum (Al).

The active layer 120 may include a p-type semiconductor compound and an n-type semiconductor compound to form a p-n junction. The active layer 120 may receive light from outside to generate excitons and then divide the generated excitons into holes and electrons.

The active layer 120 may include the organic compound according to an embodiment. For example, the active layer 120 may include a compound of Chemical Formula 1 as a p-type semiconductor compound. In an implementation, the active layer 120 including the compound of Chemical Formula 1 may have a wavelength of maximum absorption λ max of about 530 nm to about 560 nm and may exhibit an absorption curve having an FWHM of about 50 nm to about 100 nm.

The active layer 120 may have a thickness of about 50 nm to about 200 nm.

The active layer 120 may include a single layer or a multilayer including a plurality of layers. In an implementation, the active layer 120 may include a single layer including an intrinsic layer (I layer), a multilayer including a p-type layer and an I layer, a multilayer including an I layer and an n-type layer, a multilayer including a p-type layer, an I-layer, and an n-type layer, or a multilayer including a p-type layer and an n-type layer. In an implementation, the active layer 120 may include an I layer including the compound of Chemical Formula 1. In an implementation, the active layer 120 may include a p-type layer including the compound of Chemical Formula 1.

In an implementation, the active layer 120 may further include an n-type semiconductor compound. The n-type semiconductor compound may include, e.g., fullerene, a fullerene derivative, or a combination thereof (e.g., may include one or more fullerene compounds). The fullerene may be, e.g., C60, and the fullerene derivative may refer to a compound having a substituent in or on the fullerene. The fullerene derivative may include a substituent, e.g., an alkyl group, an aryl group, or a heterocyclic group. For example, the fullerene compound may include unsubstituted C60 fullerene or the substituted fullerene derivative. In an implementation, when the active layer 120 includes a compound of Chemical Formula 1 and a fullerene compound, a volume ratio of the compound of Chemical Formula 1 and the fullerene compound in the active layer 120 may be, e.g., about 7:3 to about 3:7.

The active layer 120 may have a bulk heterojunction structure including an n-type semiconductor compound and a p-type semiconductor compound including the compound of Chemical Formula 1.

In the organic photoelectric device 100, when light is incident from at least one of the first electrode 110 and the second electrode 130 and the active layer 120 absorbs light of a certain wavelength region, excitons may be generated in the active layer 120. The excitons may be divided into holes and electrons in the active layer 120, the holes may move to an anode, which is one of the first electrode 110 and the second electrode 130, the electrons may move to a cathode, which is the other of the first electrode 110 and the second electrode 130, and a current may flow through the organic photoelectric device 100.

FIG. 2 illustrates a cross-sectional view of an organic photoelectric device according to other embodiments.

Referring to FIG. 2, an organic photoelectric device 200 may have substantially the same configuration as the organic photoelectric device 100 described with reference to FIG. 1. However, the organic photoelectric device 200 may further include a first charge auxiliary layer 240 between the first electrode 110 and the active layer 120, and a second charge auxiliary layer 250 between the active layer 120 and the second electrode 130. The first charge auxiliary layer 240 and the second charge auxiliary layer 250 may facilitate the movement of holes and electrons divided in the active layer 120, thus improving the photoelectric conversion efficiency.

The first charge auxiliary layer 240 and the second charge auxiliary layer 250 may each include at least one of a hole injecting layer (HIL) for facilitating the injection of holes, a hole transporting layer (HTL) for facilitating the transport of holes, an electron blocking layer (EBL) for reducing or blocking the movement of electrons, an electron injecting layer (EIL) for facilitating the injection of electrons, an electron transporting layer (ETL) for facilitating the transport of electrons, and a hole blocking layer (HBL) for reducing or blocking the movement of holes.

The first charge auxiliary layer 240 and the second charge auxiliary layer 250 may each include an organic material, an inorganic material, or a combination thereof. The organic material may be an organic compound having the property of injecting and/or transmitting holes or electrons. The inorganic material may be a metal oxide. The metal oxide may be, e.g., a molybdenum oxide, a tungsten oxide, a nickel oxide, or a combination thereof. In an implementation, one of the first charge auxiliary layer 240 and the second charge auxiliary layer 250 may be omitted.

In an implementation, the hole transporting layer (HTL) and the electron blocking layer (EBL) may each include , e.g., poly(3,4-ethylenedioxythiophene):poly(styrenesulfonate) (PEDOT:PSS), polyarylamine, poly(N-vinylcarbazole), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA, 4,4′,4′-tris(N-carbazolyl)-triphenylamine (TCTA), or a combination thereof.

In an implementation, the electron transporting layer (ETL) and the hole blocking layer (HBL) may each include, e.g., 1,4,5,8-naphthalene-tetracarboxylic dianhydride (NTCDA), bathocuproine (BCP), LiF, Alq3, Gaq3, Inq3, Znq2, Zn(BTZ)2, BeBq2, or a combination thereof.

In an implementation, the organic photoelectric devices 100 and 200 illustrated in FIGS. 1 and 2 may be applied to solar cells, image sensors, photodetectors, photosensors, and organic light-emitting diodes.

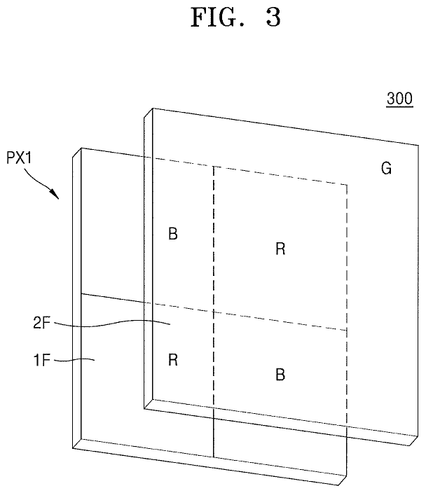

FIG. 3 illustrates a diagram of an image sensor 300 according to embodiments.

Referring to FIG. 3, the image sensor 300 may include a pixel PX1. The pixel PX1 may include an optical stack structure or an X2 structure including a first layer 1F and a second layer 2F that are stacked in a (e.g., vertical) direction.

The first layer 1F may include two red (R) unit pixels and two blue (B) unit pixels. The second layer 2F may include a green (G) unit pixel.

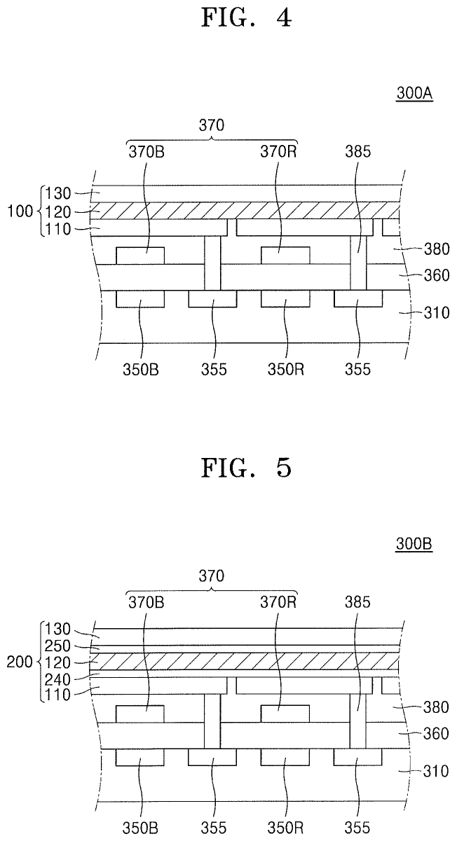

FIG. 4 illustrates a cross-sectional view of an image sensor 300A that may constitute the image sensor 300 of FIG. 3. In FIG. 4, like reference numerals as in FIG. 1 denote like elements, and repeated descriptions thereof may be omitted.

Referring to FIG. 4, the image sensor 300A may be an organic CMOS image sensor. The image sensor 300A may include a semiconductor substrate 310 in which photo-sensing devices 350B and 350R, a charge storage 355, and a transmission transistor are integrated, a lower insulating film 360, a color filter layer 370, an upper insulating film 380, and an organic photoelectric device 100.

The semiconductor substrate 310 may include a silicon substrate. The photo-sensing devices 350B and 350R may be photodiodes. The image sensor 300A may constitute the pixel PX1 illustrated in FIG. 3. In the image sensor 300A, one pixel PX1 may include the photo-sensing devices 350B and 350R, the charge storage 355, and the transmission transistor. In an implementation, the photo-sensing device 350B may sense light of a blue wavelength region and constitute a blue (B) unit pixel, the photo-sensing device 350R may sense light of a red wavelength region and constitute a red (R) unit pixel, and the charge storage 355 may constitute a green (G) unit pixel.

The photo-sensing devices 350B and 350R may sense light, and information sensed by the photo-sensing devices 350B and 350R may be transmitted by the transmission transistor. The charge storage 355 may be electrically connected to the organic photoelectric device 100. The information of the charge storage 355 may be transmitted by the transmission transistor.

In an implementation, as illustrated in FIG. 4, photo-sensing devices 350B and 350R may be arranged in a horizontal direction parallel to the extension direction of the main surface of the semiconductor substrate 310. In an implementation, the photo-sensing device 350B and the photo-sensing device 350R may be arranged to overlap each other in a vertical direction perpendicular to the extension direction of the main surface of the semiconductor substrate 310.

In an implementation, the image sensor 300A may further include a pad and a metal interconnection line covering the semiconductor substrate 310. In an implementation, the metal interconnection line and the pad may include a metal having a relatively low specific resistance to suppress signal delay, e.g., aluminum (Al), copper (Cu), silver (Ag), or an alloy thereof. The metal interconnection line and the pad may be over or under the photo-sensing devices 350B and 350R.

The lower insulating film 360 may be on the semiconductor substrate 310. The lower insulating film 360 may include a silicon oxide film, a silicon nitride film, SiC, SiCOH, SiCO, SiOF, or a combination thereof.

The color filter layer 370 may be on the lower insulating film 360. The color filter layer 370 may include a blue color filter 370B to selectively transmit light of a blue wavelength region and constituting a blue (B) unit pixel, and a red color filter 370R to selectively transmit light of a red wavelength region and constituting a red (R) unit pixel. In an implementation, the color filter layer 370 may further include a green color filter. In an implementation, the color filter layer 370 may be omitted. For example, in the case of a structure in which the photo-sensing device 350B and the photo-sensing device 350R are arranged to overlap each other in the vertical direction, the photo-sensing device 350B and the photo-sensing device 350R may selectively absorb light of a relevant wavelength region according to the stack depth thereof, and the color filter layer 370 may not be provided. The color filter layer 370 may be covered with the upper insulating film 380.

The image sensor 300A may include a through portion 385 passing through the upper insulating film 380 and the lower insulating film 360. The charge storage 355 and the first electrode 110 of the organic photoelectric device 100 may be connected to each other by the through portion 385.

The organic photoelectric device 100 may be on the upper insulating film 380. As described with reference to FIG. 1, the organic photoelectric device 100 may include the first electrode 110, the active layer 120, and the second electrode 130. The organic photoelectric device 100 may selectively absorb light of a green wavelength region. The first electrode 110 and the second electrode 130 may each be a transparent electrode. The active layer 120 may selectively absorb light of a green wavelength region and may replace a color filter constituting a green (G) unit pixel.

As for the light incident from the second electrode 130 of the organic photoelectric device 100, light of a green wavelength region may be mainly absorbed in the active layer 120 and then photoelectrically converted and light of the remaining wavelength region may be sensed by the photo-sensing devices 350B and 350R after passing through the first electrode 110. The active layer 120 of the organic photoelectric device 100 may include, e.g., the compound of Chemical Formula 1, to provide excellent selective absorption of light of a green wavelength region. For example, the active layer 120 of the organic photoelectric device 100 may be useful in the image sensor 300A.

The image sensor 300A may have a reduced size by having a structure in which the organic photoelectric device 100 selectively absorbing light of a green wavelength region is stacked. Thus, a compact image sensor 300A may be implemented.

FIG. 5 illustrates a cross-sectional view of another image sensor 300B that may constitute the image sensor 300 of FIG. 3. In FIG. 5, like reference numerals as in FIGS. 1, 2, and 4 denote like elements, and repeated descriptions thereof may be omitted.

Referring to FIG. 5, the image sensor 300B may have substantially the same configuration as the image sensor 300A described with reference to FIG. 4. However, the image sensor 300B may include the organic photoelectric device 200 illustrated in FIG. 2, instead of the organic photoelectric device 100 illustrated in FIG. 1.

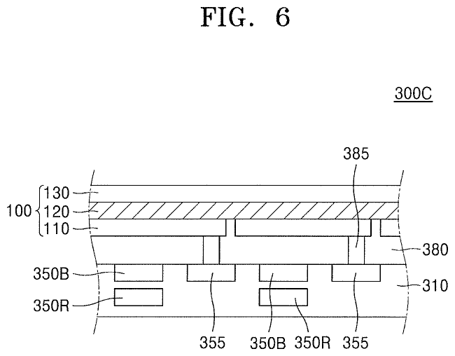

FIG. 6 illustrates a cross-sectional view of another image sensor 300C that may constitute the image sensor 300 of FIG. 3. In FIG. 6, like reference numerals as in FIGS. 1 and 4 denote like elements, and repeated descriptions thereof may be omitted.

Referring to FIG. 6, the image sensor 300C may have substantially the same configuration as the image sensor 300A described with reference to FIG. 4. However, in the image sensor 300C, the photo-sensing device 350B and the photo-sensing device 350R may overlap each other in the vertical direction. The image sensor 300C may not include the color filter layer 370, unlike the image sensor 300A illustrated in FIG. 4.

In the image sensor 300C, the photo-sensing device 350B and the photo-sensing device 350R may be electrically connectable to the charge storage 355, and the information of the charge storage 355 may be transmitted by a transmission transistor. The photo-sensing device 350B and the photo-sensing device 350R may selectively absorb light of a corresponding wavelength region according to the stack depth thereof.

The active layer 120 of the organic photoelectric device 100 may include the compound of Chemical Formula 1 to provide excellent selective absorption of light of a green wavelength region. The image sensor 300C may reduce the size of the image sensor 300C by having a structure in which the organic photoelectric device 100 selectively absorbing light of a green wavelength region is stacked. For example, a compact image sensor 300C may be implemented.

In an implementation, as illustrated in FIG. 6, the image sensor 300C may include the organic photoelectric device 100 of FIG. 1. In an implementation, the image sensor 300C may include the organic photoelectric device 200 of FIG. 2, instead of the organic photoelectric device 100 of FIG. 1.

The organic photoelectric devices 100 and 200 included in the image sensors 300A, 300B, and 300C of FIGS. 4 to 6 may provide excellent selective absorption of green light, crosstalk caused by unnecessary absorption of light of wavelength regions other than the green wavelength region may be reduced, and the sensitivity of the image sensors 300A, 300B, and 300C may be increased.

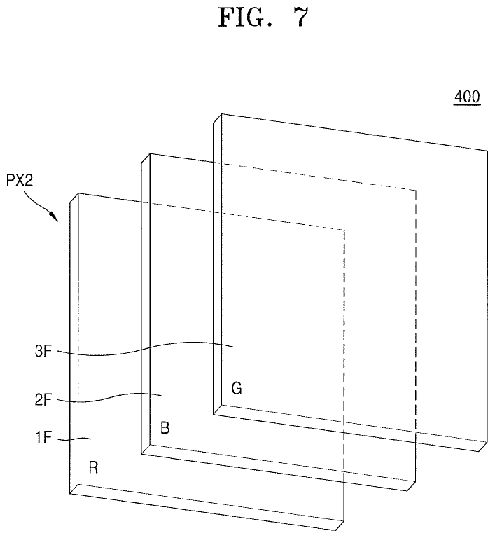

FIG. 7 illustrates a diagram of an image sensor 400 according to other embodiments.

Referring to FIG. 7, the image sensor 400 may include a pixel PX2. The pixel PX2 may include a first layer 1F, a second layer 2F, and a third layer 3F that are stacked, e.g., in the vertical direction. The first layer 1F may include a red (R) unit pixel, the second layer 2F may include a blue (B) unit pixel, and the third layer 3F may include a green (G) unit pixel. The red (R) unit pixel, the blue (B) unit pixel, and the green (G) unit pixel may overlap each other in the vertical direction.

In an implementation, as illustrated in FIG. 7, the red (R) unit pixel, the blue (B) unit pixel, and the green (G) unit pixel may be sequentially stacked in the vertical direction. In an implementation, the stack order of the red (R) unit pixel, the blue (B) unit pixel, and the green (G) unit pixel may vary according to various embodiments.

In FIG. 7, the green (G) unit pixel may include the organic photoelectric device 100 of FIG. 1, or the organic photoelectric device 200 of FIG. 2. The blue (B) unit pixel may include a pair of electrodes facing each other and an active layer located between the pair of electrodes and including an organic material that selectively absorbs light of a blue wavelength region. The red (R) unit pixel may include a pair of electrodes and an active layer between the pair of electrodes and including an organic material that selectively absorbs light of a red wavelength region.

The image sensor 400 illustrated in FIG. 7 may have a structure in which the red (R) unit pixel, the blue (B) unit pixel, and the green (G) unit pixel overlap each other in the vertical direction, and the size of the image sensor 400 may be further reduced and a compact image sensor 400 may be implemented.

The image sensors 300, 300A, 300B, 300C, and 400 described with reference to FIGS. 3 to 7 may be applied to various electronic devices such as image sensors, mobile phones, digital cameras, and biosensors.

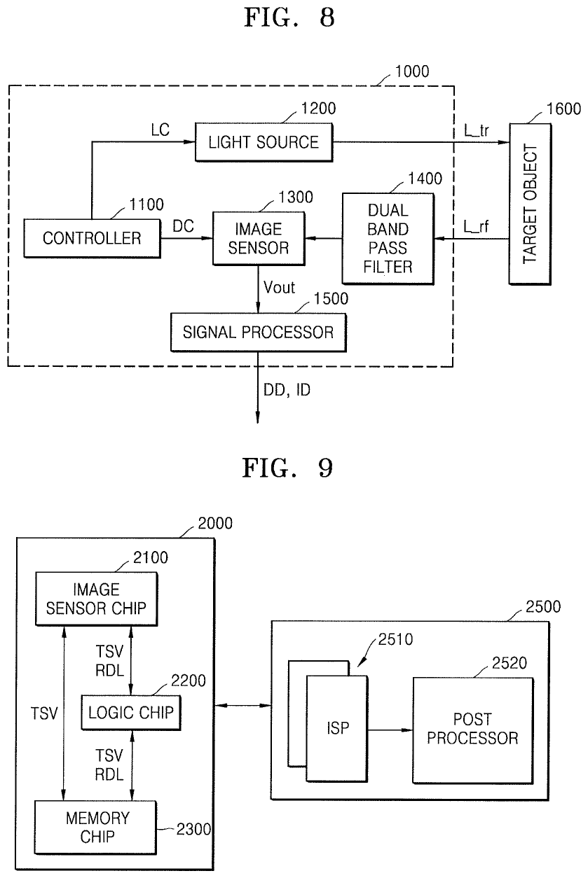

FIG. 8 illustrates a diagram of an electronic device 1000 according to embodiments. The electronic device 1000 may constitute an image sensor module. Referring to FIG. 8, the electronic device 1000 may include a controller 1100, a light source 1200, an image sensor 1300, a dual band pass filter 1400, and a signal processor 1500.

The controller 1100 may control the operation of the image sensor 1300 and each of a plurality of pixels included in the light source 1200. According to a light source control signal LC, the light source 1200 may irradiate pulse light L_tr, e.g., light with ON/OFF timing controlled, to a target object 1600 to be sensed. The pulse light L_tr periodically irradiated to the target object 1600 may be reflected from the target object 1600.

The image sensor 1300 may include a pixel array including a plurality of pixels. The image sensor 1300 may include an image sensor according to an embodiment, e.g., the image sensors 300, 300A, 300B, 300C, and 400 described with reference to FIGS. 3 to 7.

The image sensor 1300 may receive light L_rf reflected from the target object 1600 through the dual band pass filter 1400. The dual band pass filter 1400 may selectively pass light of a first wavelength and light of a second wavelength selected from a near-infrared region of the light L_rf reflected from the target object 1600. In an implementation, the light of the first wavelength and the light of the second wavelength may be, e.g., of different wavelengths respectively selected from about 810 nm and about 940 nm.

The controller 1100 may control the operation of the light source 1200 and the image sensor 1300. For example, the controller 1100 may generate the light source control signal LC of the light source 1200 and a pixel array control signal DC for controlling the pixel array included in the image sensor 1300, to control the operation of the light source 1200 and the image sensor 1300.

The image sensor 1300 may receive light of a selected wavelength from among the light L_rf reflected from the target object 1600, e.g., light of a wavelength of about 810 nm and light of a wavelength of about 940 nm, through the dual band pass filter 1400 and output a charge signal Vout according to the pixel array control signal DC received from the controller 1100.

The signal processor 1500 may output depth information DD and iris information ID based on the charge signal Vout received from the image sensor 1300.

FIG. 9 illustrates a diagram of an electronic device 2000 according to other embodiments. In an implementation, the electronic device 2000 may be an image sensor package including a CMOS image sensor.

The electronic device 2000 may include an image sensor chip 2100, a logic chip 2200, and a memory chip 2300. In an implementation, the image sensor chip 2100, the logic chip 2200, and the memory chip 2300 may be mounted on a package substrate to overlap each other in a direction perpendicular to the extension direction of the package substrate.

The image sensor chip 2100 may include an interconnection line structure and a pixel array including a plurality of unit pixels. In an implementation, the image sensor chip 2100 may include an image sensor according to an embodiment, e.g., the image sensors 300, 300A, 300B, 300C, and 400 described with reference to FIGS. 3 to 7.

The logic chip 2200 may vertically overlap the image sensor chip 2100 on the package substrate and may process a pixel signal output from the image sensor chip 2100. The memory chip 2300 may vertically overlap the image sensor chip 2100 and the logic chip 2200 on the package substrate and may store at least one of the pixel signal processed by the logic chip 2200 and the pixel signal output from the image sensor chip 2100. The memory chip 2300 may be connected to the logic chip 2200 through at least one redistribution structure RDL. The memory chip 2300 may be connected to the image sensor chip 2100 through a through silicon via (TSV) contact passing through the logic chip 2200 and the at least one redistribution structure RDL. The logic chip 2200 may vertically overlap the memory chip 2300 and the image sensor chip 2100 in a state of being between the memory chip 2300 and the image sensor chip 2100.

The image data transmitted from the pixel array block of the image sensor chip 2100 may be transmitted to a plurality of analog-to-digital converters included in the logic chip 2200, and the data transmitted from the plurality of analog-to-digital converters to the memory chip 2300 may be written into the memory cell array of the memory chip 2300.

The image signal processed by the logic chip 2200 may be transmitted to an image processing apparatus 2500. The image processing apparatus 2500 may include at least one image signal processor (ISP) 2510 and a postprocessor 2520. The image processing apparatus 2500 may output the images captured by the image sensor chip 2100, as a preview through a display, and the images captured by the image sensor chip 2100 may be stored in the memory chip 2300 when a capture command is input by a user or the like. The postprocessor 2520 may perform various operations to provide a digital image signal from the images captured by the image sensor chip 2100. For example, various postprocessing algorithms for contrast improvement, resolution improvement, noise removal, and the like, which are not performed in the ISP 2510, may be performed in the postprocessor 2520. The output from the postprocessor 2520 may be provided to a video codec processor, and the image processed through the video codec processor may be output to a display or stored in the memory chip 2300.

Next, organic compounds according to embodiments will be described in more detail. Examples of organic compounds and synthesis methods thereof described below are merely for illustrative purposes. The following Examples and Comparison Examples are provided in order to highlight characteristics of one or more embodiments, but it will be understood that the Examples and Comparison Examples are not to be construed as limiting the scope of the embodiments, nor are the Comparison Examples to be construed as being outside the scope of the embodiments. Further, it will be understood that the embodiments are not limited to the particular details described in the Examples and Comparison Examples.

### Synthesis of Chemical Formula 1a

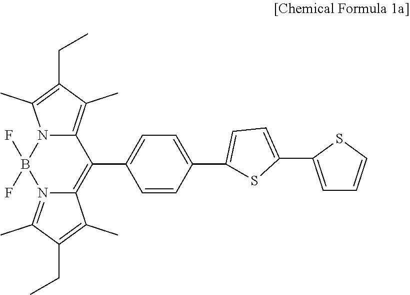

(IUPAC Name: 10-(4-([2,2′-bithiophen]-5-yl)phenyl)-2,8-diethyl-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1a was synthesized according to Reaction Formula 1.

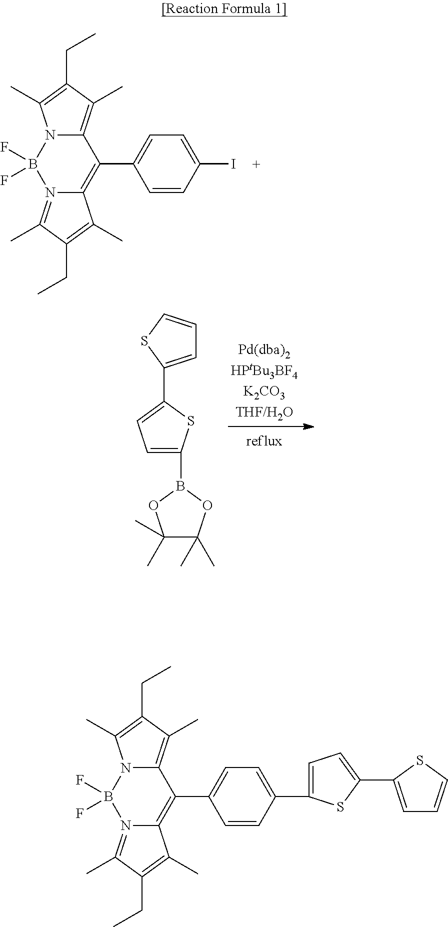

A raw compound of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinine was synthesized according to a suitable method.

In a 100 ml flask, 3.00 g (5.9 mmol) of the above raw compound, 1.81 g (6.2 mmol) of 5-(4,4,5,5-tetramethyl-1,3,2-dioxaborolan-2-yl)-2,2′-bithiophene, 0.173 g (0.30 mmol) of bis(dibenzylideneacetone)palladium, 0.174 g (0.60 mmol) of tri-tert-butylphosphonium tetrafluoroborate, 2.44 g (17.7 mmol) of potassium carbonate, 40 g of tetrahydrofuran, and 10 g of water were added and heated, refluxed, and stirred for 6 hours. Subsequently, this solution was cooled to ambient temperature and then cleaned with toluene and water, and an oil layer thereof was concentrated under reduced pressure and then sublimated/purified to obtain 1.50 g of Chemical Formula 1a.

A compound thereof was identified by ¹H-NMR (Nuclear Magnetic Resonance).

¹H-NMR(CDCl₃,ppm):δ=0.99 (t, J=7.6 Hz, 6H), 1.38 (s, 6H), 2.31 (q, J=7.6 Hz, 4H), 2.54 (s, 6H), 7.04-7.07 (m, 1H), 7.19 (d, J=4 Hz, 1H), 7.23-7.25 (m, 2H), 7.30 (d, J=7.6 Hz, 1H), 7.34 (d, J=3.6 Hz, 1H), 7.73 (d, J=10.4 Hz, 2H)

### Synthesis of Chemical Formula 1b

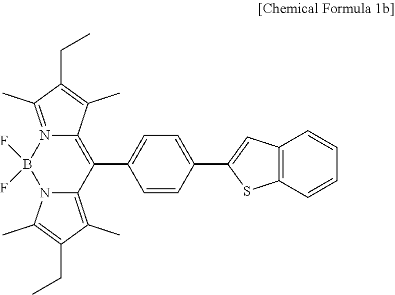

(IUPAC Name: 10-(4-(benzo[b]thiophen-2-yl)phenyl)-2,8-diethyl-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1b was synthesized according to Reaction Formula 2.

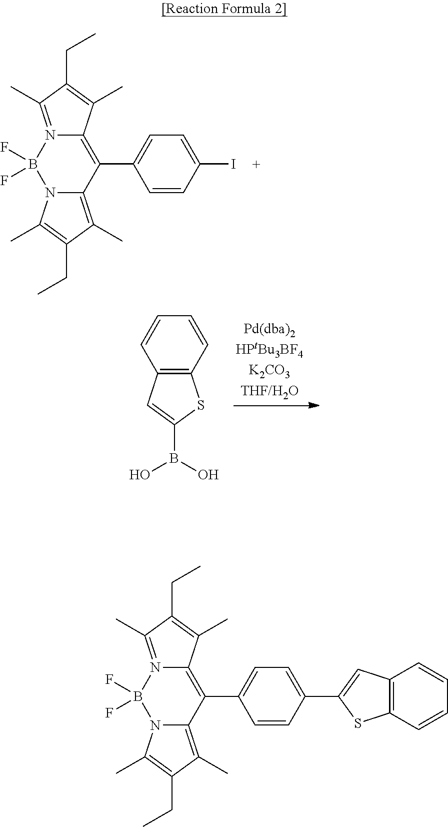

A raw compound of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinine was synthesized in the same way as in the synthesis of the compound of Chemical Formula 1a.

In a 100 ml flask, 2 g (3.9 mmol) of the above raw compound, 0.7 g (3.9 mmol) of benzo[b]thiophene-2-boronic acid, 57 mg (0.1 mmol) of bis(dibenzylideneacetone)palladium, 0.06 g (0.2 mmol) of tri-tert-butylphosphonium tetrafluoroborate, 1.6 g (11.8 mmol) of potassium carbonate, 40 g of tetrahydrofuran, and 10 g of water were added and refluxed and stirred for 6 hours. This solution was cooled to ambient temperature, water was added thereto, and a red solid obtained by filtering a reaction mixture thereof was sublimated and purified to recover 0.6 g of Chemical Formula 1b.

A compound thereof was identified by ¹H-NMR.

¹H-NMR(CDCl₃,ppm):δ=0.99 (t, J=7.6 Hz, 6H), 1.38 (s, 6H), 2.31 (q, J=7.6 Hz, 4H), 2.54 (s, 6H), 7.35 (m, 4H), 7,67 (s, 1H), 7.80-7.87 (m, 4H).

### Synthesis of Chemical Formula 1c

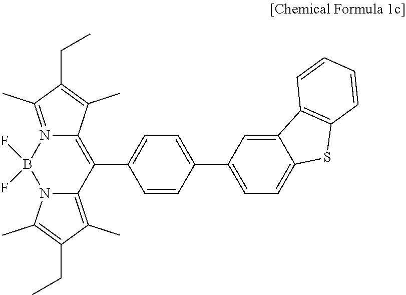

(IUPAC Name: 10-(4-(dibenzo[b,d]thiophen-2-yl)phenyl)-2,8-diethyl-5,5difluoro-1,3,7,9-tetramethyl-5H-4λ⁴,5λ⁴-dipyrrolo[1,2-c:2′,1′-f][1,3,2]diazaborinine)

A compound of Chemical Formula 1c was synthesized according to Reaction Formula 3.

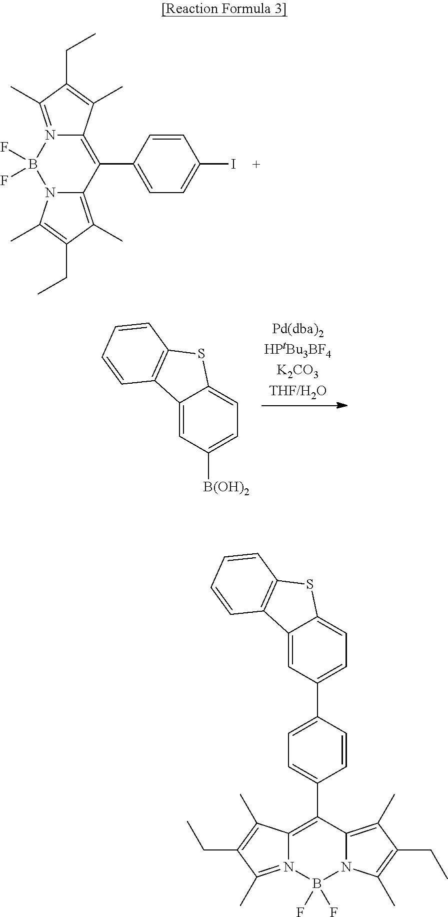

A raw compound of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinine was synthesized in the same way as in the synthesis of the compound of Chemical Formula 1a.

In a 100 ml flask, 2 g (3.9 mmol) of the above raw compound, 0.9 g (3.9 mmol) of dibenzo[b,d]thien-2-ylboronic acid, 57 mg (0.1 mmol) of bis(dibenzylideneacetone)palladium, 0.06 g (0.2 mmol) of tri-tert-butylphosphonium tetrafluoroborate, 1.6 g (11.8 mmol) of potassium carbonate, 40 g of tetrahydrofuran, and 10 g of water were added and refluxed and stirred for 6 hours. This solution was cooled to ambient temperature, water was added thereto, and a red solid obtained by filtering a reaction mixture thereof was sublimated and purified to recover 0.51 g of Chemical Formula 1c.

A compound thereof was identified by ¹H-NMR.

¹H-NMR(CDCl₃,ppm):δ=1.02 (t, J=7.6 Hz, 6H), 1.40 (s, 6H), 2.33 (q, J=7.6 Hz, 4H), 2.56 (s, 6H), 7.41-7.43 (m, 2H), 7.50-7.53 (m, 2H), 7.80 (d, J=5 Hz, 1H), 7.85-7.91 (m, 3H), 7.96 (d, J=4.2 Hz, 1H), 8.27 (dd, J=4.4 Hz, 1H), 8.45 (s, 1H).

### Synthesis of Chemical Formula 1d

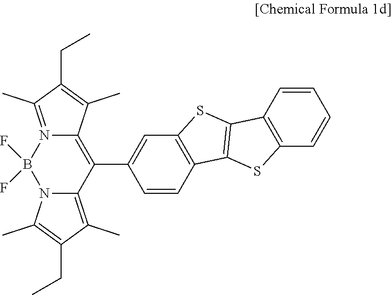

(IUPAC Name: 10-(benzo[b]benzo[4,5]thieno[2,3-d]thiophen-2-yl)-2,8-diethyl-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1d was synthesized according to Reaction Formula 4.

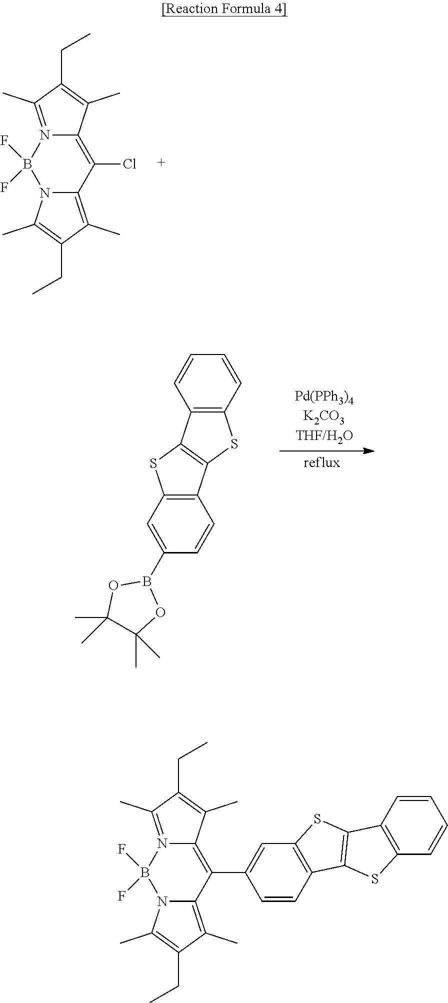

A raw compound of 10-chloro-2,8-diethyl-5,5-difluoro-1,3,7,9-tetramethyl-5H-4λ⁴,5λ⁴-dipyrrolo[1,2-c:2′,1′-f][1,3,2]diazaborinine was synthesized by a suitable method. A raw compound of 2-(benzo[b]benzo[4,5]thieno[2,3-d]thiophen-2-yl)-4,4,5,5-tetramethyl-1,3,2-dioxaborolane was synthesized by a suitable method.

In a 20 ml flask, 0.340 g (1 mmol) of 10-chloro-2,8-diethyl-5,5-difluoro-1,3,7,9-tetramethyl-5H-4λ⁴,5λ⁴-dipyrrolo[1,2-c:2′,1′-f][1,3,2]diazaborinine, 0.385 g (1.05 mmol) of 2-(benzo[b]benzo[4,5] thieno[2,3-d]thiophen-2-yl)-4,4,5,5-tetramethyl-1,3,2-dioxaborolane, 57.8 mg (0.05 mmol) of tetrakis(triphenylphosphine)palladium(0), 0.415 g (3 mmol) of potassium carbonate, 4 g of tetrahydrofuran, and 1 g of water were added and heated, refluxed, and stirred for 6 hours. This solution was cooled to ambient temperature and then cleaned with toluene and water, and an oil layer thereof was concentrated under reduced pressure to obtain a red solid. It was purified by silica gel column chromatography (Toluene/Hexane =1/1) and then sublimated and purified to recover 0.233 g of Chemical Formula 1d.

A compound thereof was identified by ¹H-NMR.

¹H-NMR(CDCl₃,ppm):δ=0.98 (t, J=7.6 Hz, 6H), 1.28 (s, 6H), 2.30 (q, J=7.6 Hz, 4H), 2.56 (s, 6H), 7.39 (d, J=8.4 Hz, 1H), 7.52-7.45 (m, 2H), 7.85 (s, 1H), 7.92 (d, J=7.6 Hz, 1H), 7.97 (d, J=8.0 Hz, 1H), 8.01 (d, J=8.4 Hz, 1H)

### Synthesis of Chemical Formula 1e

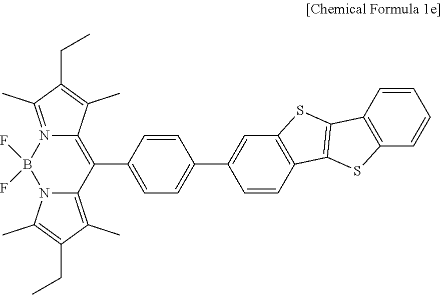

(IUPAC Name: 10-(4-(benzo[b]benzo[4,5]thieno[2,3-d]thiophen-2-yl)phenyl)-2,8-diethyl-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1e was synthesized according to Reaction Formula 5.

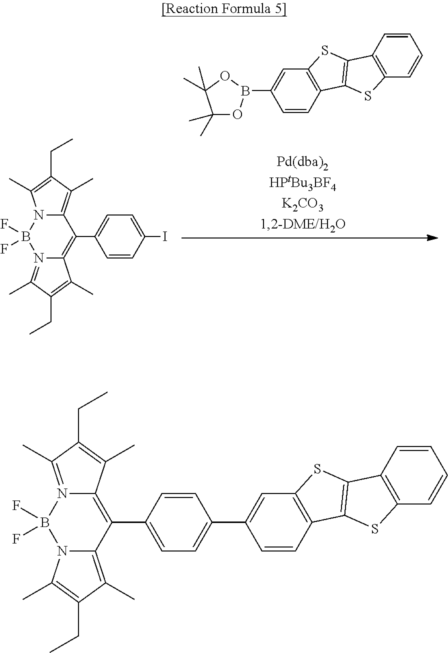

A raw compound of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinine was synthesized in the same way as in the synthesis of the compound of Chemical Formula 1a. A raw compound of 2-(benzo[b]benzo[4,5]thieno[2,3-d]thiophen-2-yl)-4,4,5,5-tetramethyl-1,3,2-dioxaborolane was synthesized in the same way as in the synthesis of the compound of Chemical Formula 1d.

In a 100 ml flask, 2.0 g (3.9 mmol) of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinine, 1.4 g (3.9 mmol) of 2-(benzo[b]benzo[4,5] thieno[2,3-d]thiophen-2-yl)-4,4,5,5-tetramethyl-1,3,2-dioxaborolane, 57 mg (0.1 mmol) of bis(dibenzylideneacetone)palladium, 57 mg (0.2 mmol) of tri-tert-butylphosphonium tetrafluoroborate, 1.6 g (11.8 mmol) of potassium carbonate, 40 g of 1,2-dimethoxyethane, and 10 g of water were added and heated, refluxed, and stirred for 6 hours. This solution was cooled to ambient temperature, water was added thereto, and a red solid obtained by filtering a reaction mixture thereof was sublimated/purified to recover 0.49 g of Chemical Formula 1e.

A compound thereof was identified by ¹H-NMR.

¹H-NMR(CDCl₃,ppm):δ=1.00 (t, J=7.6 Hz, 6H), 1.39 (s, 6H), 2.32 (q, J=7.6 Hz, 4H), 2.55 (s, 6H), 7.40-7.52 (m, 4H), 7.79-7.86 (m, 3H), 7.91-8.00 (m, 3H), 8.24 (s, 1H).

### Synthesis of Chemical Formula 1f

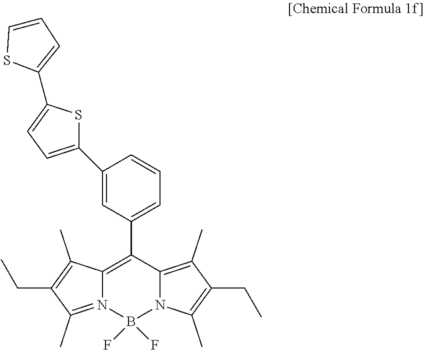

(IUPAC Name: 10-(3-([2,2′-bithiophen]-5-yl)phenyl)-2,8-diethyl-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1f was synthesized according to Reaction Formula 6.

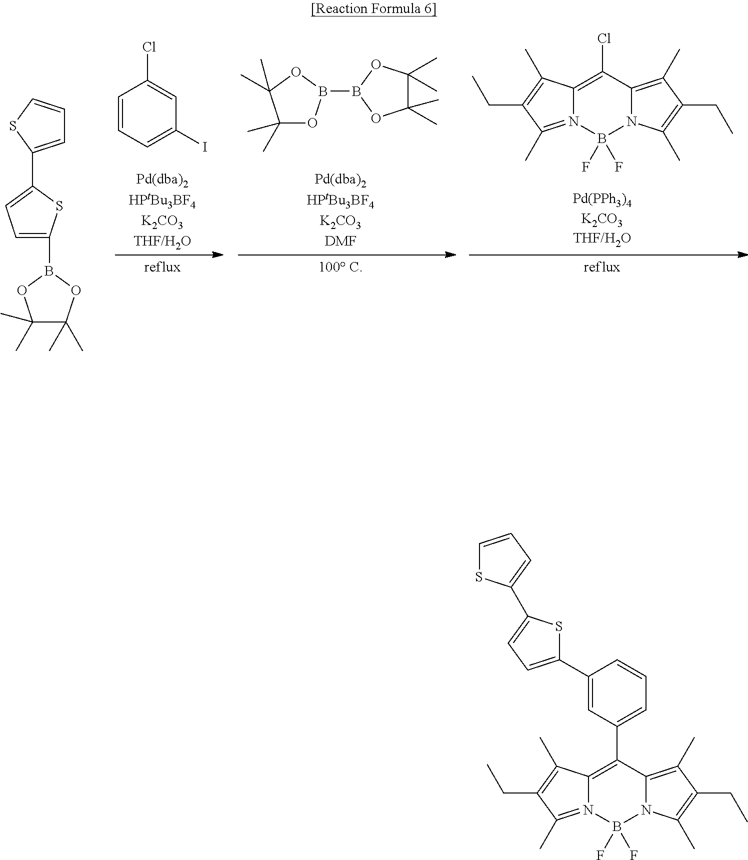

A raw compound of 10-chloro-2,8-diethyl-5,5-difluoro-1,3,7,9-tetramethyl-5H-4λ⁴,5λ⁴-dipyrrolo[1,2-c:2′,1′-f][1,3,2]diazaborinine was synthesized in the same way as in the synthesis of the compound of Chemical Formula 1d.

In a 20 ml flask, 1.02 g (3.5 mmol) of 5-(4,4,5,5-tetramethyl-1,3,2-dioxaborolan-2-yl)-2,2′-bithiophene, 0.835 g (3.5 mmol) of 1-chloro-3-iodobenzene, 0.101 g (0.175 mmol) of bis(dibenzylideneacetone)palladium, 0.102 g (0.35 mmol) of tri-tert-butylphosphonium tetrafluoroborate, 1.45 g (10.5 mmol) of potassium carbonate, 12 g of tetrahydrofuran, and 3 g of water were added and heated, refluxed, and stirred for 6 hours. Subsequently, this solution was cooled to ambient temperature and then cleaned with toluene and water, and an oil layer thereof was concentrated under reduced pressure to obtain 0.698 g of pale green solid. Subsequently, in a 20 ml flask, a total amount (2.52 mmol) of the obtained crude product, 0.704 g (2.77 mmol) of 4,4,4′,4′,5,5,5′,5′-octamethyl-2,2′-bi(1,3,2-dioxaborolane), 14 mg (0.0252 mmol) of bis(dibenzylideneacetone)palladium, 14.6 g (0.0504 mmol) of tri-tert-butylphosphonium tetrafluoroborate, 1.04 g (7.56 mmol) of potassium carbonate, and 10 g of N,N-dimethylformamide were added and refluxed at 100° C. for 6 hours. This solution was cooled to ambient temperature and then cleaned with toluene and water, and an oil layer thereof was concentrated under reduced pressure to obtain 0.464 g of pale yellow solid. Subsequently, in a 20 ml flask, a total amount (1.26 mmol) of the obtained crude product, 0.408 g (1.2 mmol) of 10-chloro-2,8-diethyl-5,5-difluoro-1,3,7,9-tetramethyl-5H-4λ⁴,5λ⁴-dipyrrolo[1,2-c:2′,1′-f][1,3,2]diazaborinin, 69 mg (0.06 mmol) of tetrakis(triphenylphosphine)palladium(0), 0.498 g (3.6 mmol) of potassium carbonate, 12 g of tetrahydrofuran, and 3 g of water were added and heated, refluxed, and stirred for 6 hours. This solution was cooled to ambient temperature and then cleaned with toluene and water, and an oil layer thereof was concentrated under reduced pressure to obtain a red solid. It was purified by silica gel column chromatography (Toluene/Hexane=1/1) and then sublimated and purified to recover 0.415 g of Chemical Formula 1f.

A compound thereof was identified by ¹H-NMR.

¹H-NMR(CDCl₃,ppm):δ=0.99 (t, J=7.6 Hz, 6H), 1.38 (s, 6H), 2.31 (q, J=7.5 Hz, 4H), 2.55 (s, 6H), 7.04-7.00 (m, 1H), 7.16 (d, J=3.6, 1H), 7.20-7.28 (m, 4H), 7.50 (t, J=7.8 Hz, 1H), 7.56 (s, 1H), 7.71 (d, J=4.4 Hz, 1H)

### Synthesis of Chemical Formula 1g

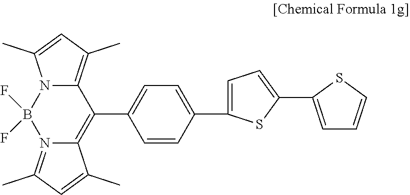

(IUPAC Name: 10-(4-([2,2′-bithiophen]-5-yl)phenyl)-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1g was synthesized according to Reaction Formula 7.

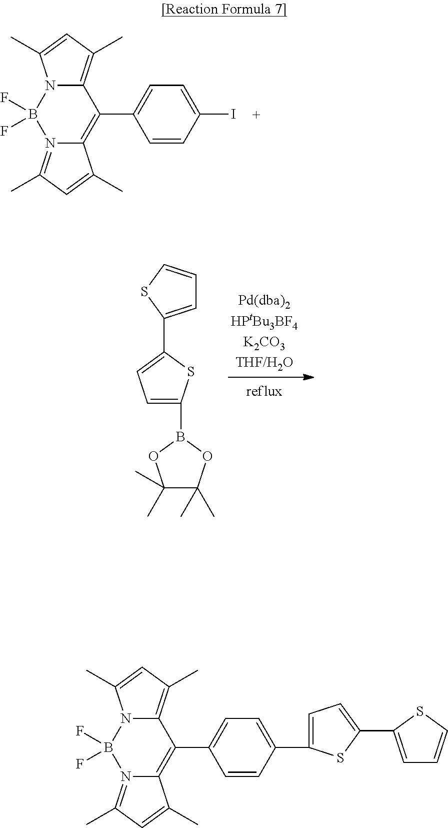

In a 50 ml flask, 0.900 g (2.0 mmol) of [1-[(3,5-Dimethyl-1H-pyrrol-2-yl)-(3,5-dimethyl-2H-pyrrol-2-ylidene)-methyl]-4-iodobenzene](difluorobororane), 0.643 g (2.2 mmol) of 5-(4,4,5,5-tetramethyl-1,3,2-dioxaborolan-2-yl)-2,2′-bithiophene, 57.5 mg (0.1 mmol) of bis(dibenzylideneacetone)palladium, 58.4 mg (0.2 mmol) of tri-tert-butylphosphonium tetrafluoroborate, 0.829 g (6.0 mmol) of potassium carbonate, 12 g of tetrahydrofuran, and 3 g of water were added and heated, refluxed, and stirred for 8 hours. This solution was cooled to ambient temperature, water was added thereto, and a red solid obtained by filtering a reaction mixture thereof was sublimated/purified to recover 0.395 g of Chemical Formula 1g.

A compound thereof was identified by ¹H-NMR.

¹H-NMR(CDCl₃,ppm):δ=1.48 (s, 6H), 2.56 (s, 6H), 7.04-7.06 (m, 1H), 7.19 (d, J=4.0 Hz, 1H), 7.23-7.26 (m, 2H), 7.3 (d, J=8.4 Hz, 2H), 7.34 (d, J=3.6 Hz, 1H), 7.74 (d, J=8.4 Hz, 2H)

### Synthesis of Chemical Formula 1h

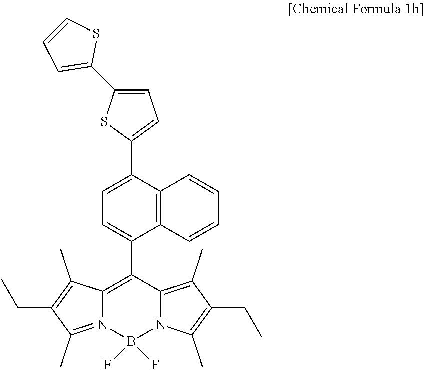

(IUPAC Name: 10-(4-([2,2′-bithiophen]-5-yl)naphthalen-l-yl)-2,8-diethyl-5,5-difluoro-1,3,7,9-tetramethyl-5H-4λ⁴,5λ⁴-dipyrrolo[1,2-c:2′,1′-f][1,3,2]diazaborinine)

A compound of Chemical Formula 1h was synthesized according to Reaction Formula 8.

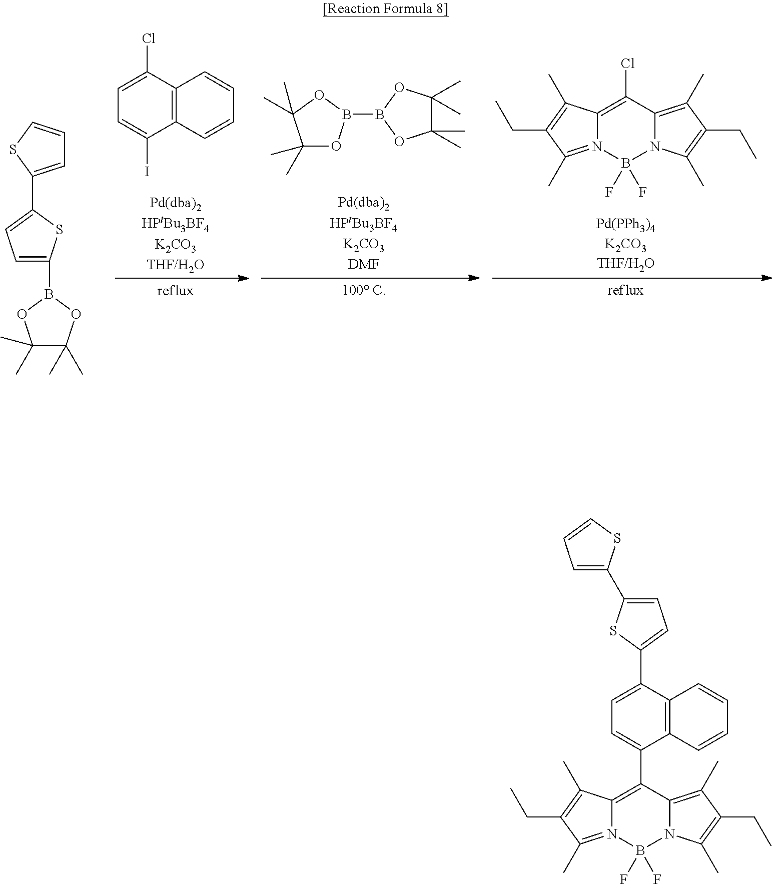

A raw compound of 10-chloro-2,8-diethyl-5,5-difluoro-1,3,7,9-tetramethyl-5H-4λ⁴,5λ⁴-dipyrrolo[1,2-c:2′,1′-f][1,3,2]diazaborinine was synthesized in the same way as in the synthesis of the compound of Chemical Formula 1d.

In a 20 ml flask, 0.845 g (2.9 mmol) of 5-(4,4,5,5-tetramethyl-1,3,2-dioxaborolan-2-yl)-2,2′-bithiophene, 0.835 g (2.9 mmol) of 1-chloro-4-iodonaphthalene, 0.101 g (0.175 mmol) of bis(dibenzylideneacetone)palladium, 0.102 g (0.35 mmol) of tri-tert-butylphosphonium tetrafluoroborate, 1.45 g (10.5 mmol) of potassium carbonate, 12 g of tetrahydrofuran, and 3 g of water were added and heated, refluxed, and stirred for 6 hours. This solution was cooled to ambient temperature and then cleaned with toluene and water, and an oil layer thereof was concentrated under reduced pressure to obtain 0.698 g of pale green solid. Subsequently, in a 20 ml flask, a total amount (2.52 mmol) of the obtained crude product, 0.704 g (2.77 mmol) of 4,4,4′,4′,5,5,5′,5′-octamethyl-2,2′-bi(1,3,2-dioxaborolane), 14 mg (0.0252 mmol) of bis(dibenzylideneacetone)palladium, 14.6 g (0.0504 mmol) of tri-tert-butylphosphonium tetrafluoroborate, 1.04 g (7.56 mmol) of potassium carbonate, and 10 g of N,N-dimethylformamide were added and refluxed at 100° C. for 6 hours. This solution was cooled to ambient temperature and then cleaned with toluene and water, and an oil layer thereof was concentrated under reduced pressure to obtain 0.464 g of pale yellow solid. Subsequently, in a 20 ml flask, a total amount (1.37 mmol) of the obtained crude product, 0.573 g (1.37 mmol) of 10-chloro-2,8-diethyl-5,5-difluoro-1,3,7,9-tetramethyl-5H-4λ⁴,5λ⁴-dipyrrolo[1,2-c:2′,1′-f][1,3,2]diazaborinin, 69 mg (0.06 mmol) of tetrakis(triphenylphosphine)palladium(0), 0.498 g (3.6 mmol) of potassium carbonate, 12 g of tetrahydrofuran, and 3 g of water were added and heated, refluxed, and stirred for 6 hours. This solution was cooled to ambient temperature and then cleaned with toluene and water, and an oil layer thereof was concentrated under reduced pressure to obtain a red solid. It was purified by silica gel column chromatography (Toluene/Hexane=1/1) and then sublimated and purified to recover 0.415 g of Chemical Formula 1h.

A compound thereof was identified by ¹H-NMR.

¹H-NMR(CDCl₃,ppm):δ=0.99 (t, J=7.6 Hz,6H), 1.05 (s, 6H), 2.31 (q, J=7.5 Hz, 4H), 2.55 (s, 6H), 7.06-7.08 (m, 1H), 7.15-7.19 (m, 2H), 7.23-7.25 (m, 1H), 7.28 -7.30 (m, 1H), 7.42 (d, J=3.6 Hz, 1H), 7.45-7.49 (m, 1H), 7.53-7.57 (m, 1H), 7.69 (d , J=4.4 Hz, 1H), 7.90 (d , J=4.4 Hz, 1H), 8.40 (d, J=4.4 Hz, 1H)

### Synthesis of Chemical Formula 1i

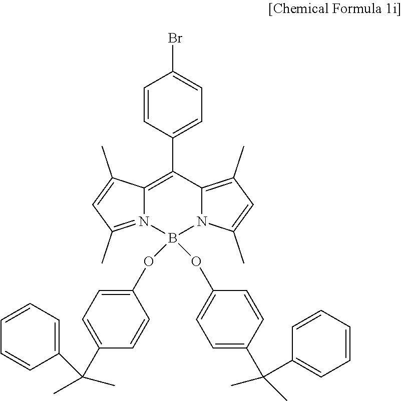

(IUPAC Name: 10-(4-bromophenyl)-1,3,7,9-tetramethyl-5,5-bis(4-(2-phenylpropan-2-yl)phenoxy)-5H-4λ⁴,5λ⁴-dipyrrolo[1,2-c:2′,1′-f][1,3,2]diazaborinine)

A compound of Chemical Formula 1i was synthesized according to Reaction Formula 9.

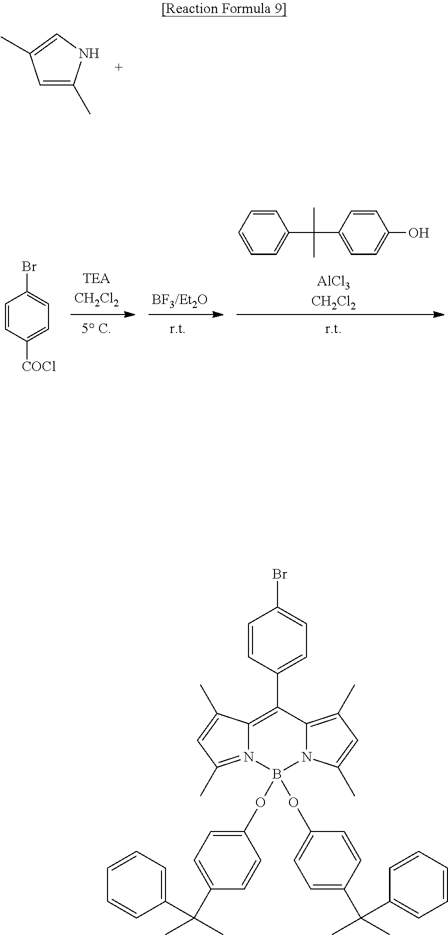

In a 200 ml flask, 4.8 g (50 mmol) of 2,4-dimethylpyrrole, 5.5 g (25 mmol) of 4-bromobenzoyl chloride, and 70 g of dichloromethane were added and stirred at ambient temperature for 6 hours, and then this solution was cooled to 5° C. and 10 g (99 mmol) of triethylamine was added and it was stirred for 1 hour. Subsequently, 10 g (70 mmol) of boron trifluoride-ethyl ether complex was added, and it was stirred at ambient temperature for 1 hour. Thereafter, the solution was cleaned and the oil layer was concentrated to obtain 7.5 g of a red orange solid. Subsequently, in a 100 ml flask, 0.6 g of the obtained red orange solid, 0.3 g (2.2 mmol) of aluminum chloride, 60 g of dichloromethane, and 11.6 g (55 mmol) of 4-α-cumylphenol were added and stirred for 2 hours. Subsequently, water was added to this solution, oil-water separation was performed, and the oil layer was concentrated under reduced pressure to obtain 0.5 g of a red orange solid. The obtained red orange solid was purified by silica gel column chromatography to recover 0.2 g of Chemical Formula 1i.

A compound thereof was identified by ¹H-NMR.

¹H-NMR(CDCl₃,ppm):δ=1.50 (s, 6H), 1.60 (s, 12H), 2.55 (s, 6H), 5.88 (s, 2H), 6.46 (d, J=4.2 Hz, 2H), 6.86 (d, J=4.2 Hz, 4H), 6.98 (d, J=8 Hz, 2H), 7.11-7.25 (m, 10H), 7.57 (d, J=8 Hz, 2H).

### Synthesis of Chemical Formula 1j

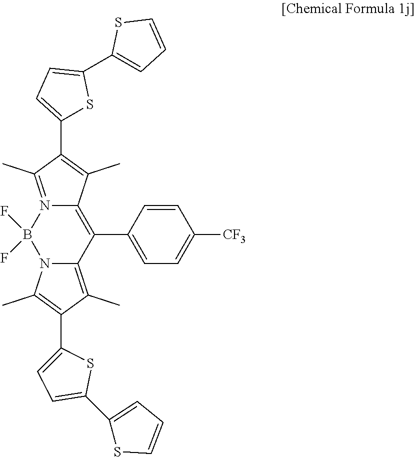

(IUPAC Name: 2,8-di([2,2′-bithiophen]-5-yl)-5,5-difluoro-1,3,7,9-tetramethyl-10-(4-(trifluoromethyl)phenyl)-5H-4λ⁴,5λ⁴-dipyrrolo[1,2-c:2′,1′-f][1,3,2]diazaborinine)

A compound of Chemical Formula 1j was synthesized according to Reaction Formula 10.

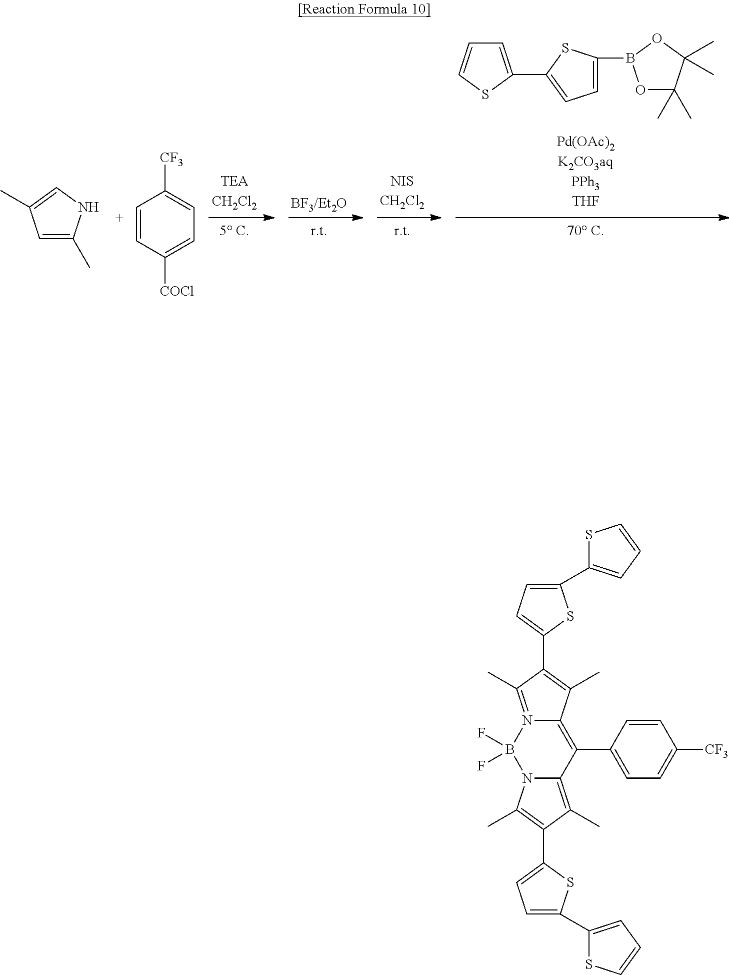

In a 200 ml flask, 4.8 g (50 mmol) of 2,4-dimethylpyrrole, 5.3 g (25 mmol) of 4-(trifluoromethyl)benzoyl chloride, and 70 g of dichloromethane were added and stirred at ambient temperature for 14 hours, and then this solution was cooled to 5° C. and 10 g (99 mmol) of triethylamine was added and it was stirred for 3 hours. Subsequently, 10 g (70 mmol) of boron trifluoride-ethyl ether complex was added, and it was stirred at ambient temperature for 1 hour. Thereafter, the solution was cleaned and the oil layer was concentrated under reduced pressure to obtain 2.4 g of a red orange solid. Subsequently, in a 100 ml flask, 1.0 g of the obtained red orange solid, 20 g of dichloromethane, and 5.6 g (25 mmol) of N-iodosuccinimide were added and then it was stirred at ambient temperature for 14 hours. Subsequently, water was added to this solution, oil-water separation was performed, and the oil layer was concentrated under reduced pressure to obtain 0.5 g of a red orange solid. In a 30 ml flask, a total amount (0.78 mmol) of the red orange solid, 0.57 g (2.0 mmol) of 5-(4,4,5,5-tetramethyl-1,3,2-dioxaborolan-2-yl)-2,2′-bithiophene, 20 mg (0.089 mmol) of palladium acetate, 100 mg (0.38 mmol) of triphenylphosphine, 83 mg (600 mmol) of potassium carbonate, 10 g of tetrahydrofuran, and 2.5 g of water were added and refluxed at 70° C. for 17 hours. The obtained red orange solid was purified by silica gel column chromatography to recover 0.2 g of Chemical Formula 1j.

A compound thereof was identified by ¹H-NMR.

¹H-NMR(CDCl₃,ppm):δ=1.40 (s, 6H), 2.59 (s, 6H), 6.76 (d, J=3.6 Hz, 2H), 6.97-7.00 (m, 2H), 7.13-7.25 (m, 6H) 7.52 (d, J=8 Hz, 2H), 7.81 (d, J=8 Hz, 2H).

### Synthesis of Chemical Formula 1k

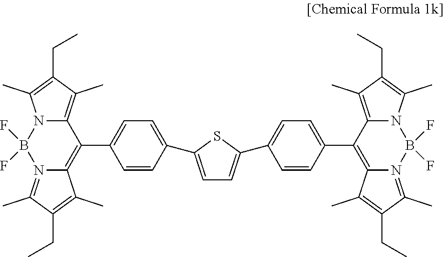

(IUPAC Name: 2,5-bis(4-(2,8-diethyl-5,5-difluoro-1,3,7,9-tetramethyl-5H-4λ⁴,5λ⁴-dipyrrolo[1,2-c:2′,1′-f][1,3,2]diazaborinin-10-yl)phenyl)thiophene)

A compound of Chemical Formula 1k was synthesized according to Reaction Formula 11.

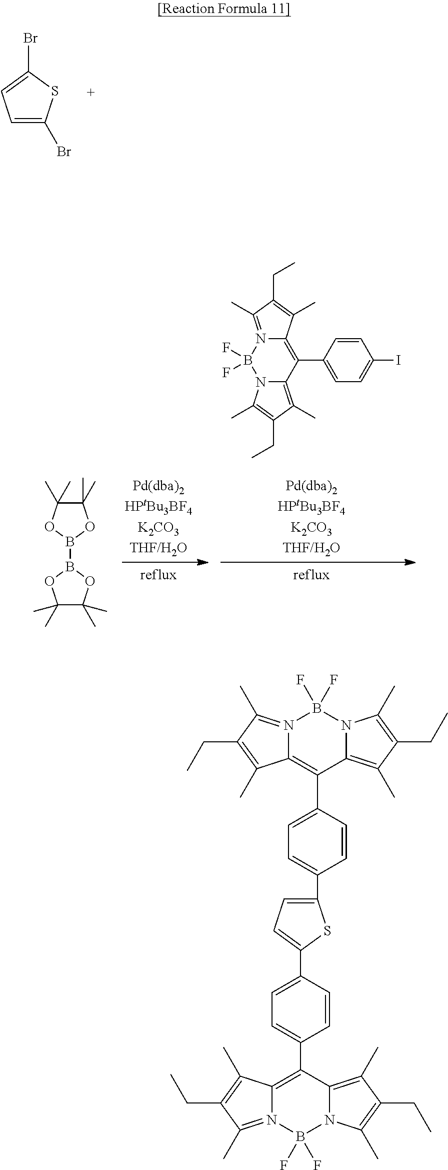

A raw compound of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinine was synthesized in the same way as in the synthesis of the compound of Chemical Formula 1a.

In a 50 ml flask, 1.45 g (6.0 mmol) of 2,5-dibromothiophene, 3.35 g (13.2 mmol) of 4,4,4′,4′,5,5,5′,5′-octamethyl-2,2′-bi(1,3,2-dioxaborolane), 35 mg (0.06 mmol) of bis(dibenzylideneacetone)palladium, 34.8 mg (0.12 mmol) of tri-tert-butylphosphonium tetrafluoroborate, 4.98 g (36 mmol) of potassium carbonate, and 40 g of tetrahydrofuran were added and heated, refluxed, and stirred for 8 hours. This solution was cooled to ambient temperature and then cleaned with toluene and water, and the oil layer was concentrated under reduced pressure to obtain a brown solid. This brown solid was purified by silica gel column chromatography (toluene), and then 0.80 g of a white solid was obtained. Subsequently, in a 50 ml flask, 0.504 g (1.5 mmol) of the obtained white solid, 1.41 g (3.06 mmol) of 2,8-diethyl-5,5-difluoro-10-(4-iodophenyl)-1,3,7,9-tetramethyl-5H-4λ⁴,5λ⁴-dipyrrolo[1,2-c:2′,1′-f][1,3,2]diazaborinin, 86.3 mg (0.15 mmol) of bis(dibenzylideneacetone)palladium, 87 mg (0.3 mmol) of tri-tert-butylphosphonium tetrafluoroborate, 1.24 g (9 mmol) of potassium carbonate, 12 g of tetrahydrofuran, and 3 g of water were added and heated, refluxed, and stirred for 8 hours. This solution was cooled to ambient temperature and then cleaned with tetrahydrofuran (THF) and water, and the oil layer was concentrated under reduced pressure to obtain a brown solid. The brown solid was purified by silica gel column chromatography (toluene) to recover 0.62 g of Chemical Formula 1k.

A compound thereof was identified by ¹H-NMR.

¹H-NMR(CDCl₃,ppm):δ=0.97 (t, J=7.4 Hz, 12H), 1.39 (s, 12H), 2.32 (q, J=7.3 Hz, 8H), 2.55 (s, 12H), 7.33 (d, J=7.6 Hz, 4H), 7.45 (s, 2H), 7.78 (d, J=8.0 Hz, 4H)

### Synthesis of Chemical Formula 1l

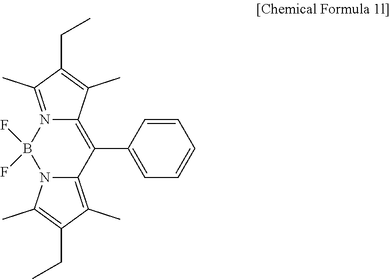

(IUPAC Name: 2,8-diethyl-5,5-difluoro-1,3,7,9-tetramethyl-10-phenyl-5H-4λ⁴,5λ⁴-dipyrrolo[1,2-c:2′,1′-f][1,3,2]diazaborinine)

Chemical Formula 1l was a reagent from Aldrich. Sublimation purification was performed to recover Chemical Formula 1l.

A compound thereof was identified by 1H-NMR.

¹H-NMR(CDCl₃,ppm):δ=7.40-7.37 (m, 3H), 7.21-7.17 (m, 2H), 2.45 (s, 6H), 2.22 (q, J=7.5 Hz, 4H), 1.20 (s, 6H), 0.90 (t , J=7.5 Hz, 6H).

### Synthesis of Chemical Formula 1m

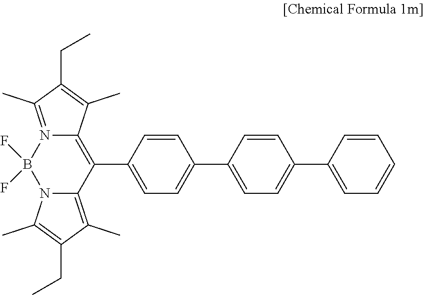

(IUPAC Name: 10-([1,1′:4′,1″-terphenyl]-4-yl)-2,8-diethyl-5,5-difluoro-1,3,7,9-tetramethyl-5H-4λ⁴,5λ⁴-dipyrrolo[1,2-c:2′,1′-f][1,3,2]diazaborinine)

As for a compound of Chemical Formula 1m, 5-(4,4,5,5-tetramethyl-1,3,2-dioxaborolan-2-yl)-2,2′-bithiophene used in the synthesis of the compound of Chemical Formula 1a was reacted with 2-(4-biphenyl)-4,4,5,5-tetramethyl-1,3,2-dioxaborolane, and the same operation was performed at the same molar mixing ratio as in the synthesis of the compound of Chemical Formula 1a to recover 1.60 g of Chemical Formula 1m.

Also, a compound thereof was identified by ¹H-NMR.

¹H-NMR(CDCl₃,ppm):δ=0.99 (t, J=7.6 Hz, 6H), 1.37 (s, 6H), 2.31 (q, J=7.3 Hz, 4H), 2.55 (s, 6H), 7.36-7.40 (m, 3H), 7.50 (t, J=7.6 Hz, 2H), 7.67 (d, J=7.6 Hz, 2H), 7.73 (d, J=8.4 Hz, 2H), 7.78-7.61 (m, 4H)

Next, the physical properties of organic compounds according to embodiments will be described below.

Table 1 shows the results of evaluating the physical properties of organic compounds according to Examples, together with the results of Comparison Examples.

TABLE 1

| | | | | | | Absorption | | | | | |
|---|---|---|---|---|---|---|---|---|---|---|---|
| | | λ max [nm] | | FWHM [nm] | | Coefficient | | | Thermal Property (° C.) | | |
| | | | Thin | | Thin | ×10⁴ cm⁻¹ | Energy Level (eV) | | | Ts | Td |
| | C.F. | Solution | Film | Solution | Film | (Thin Film) | HOMO | LUMO | Tm | (−10%) | (−10%) |
| Ex. 1 | 1a | 528 | 537 | 25 | 74 | 8.0 | −5.8 | −3.7 | 272 | 309 | 359 |
| Ex. 2 | 1b | 528 | 541 | 25 | 60 | 8.0 | −5.8 | −3.7 | 340 | 310 | 358.3 |
| Ex. 3 | 1c | 527 | 540 | 25 | 52 | 9.7 | −5.8 | −3.6 | 304 | 320 | 364.6 |
| Ex. 4 | 1d | 529 | 542 | 25 | 56 | 12.3 | −5.8 | −3.7 | N.D. | 301 | 353 |
| Ex. 5 | 1e | 528 | 541 | 25 | 56 | 11.8 | −5.8 | −3.6 | 312 | 338 | 395 |
| Ex. 6 | 1f | 528 | 542 | 25 | 57 | 11.6 | −5.8 | −3.7 | 231 | 288 | 335 |
| Ex. 7 | 1g | 504 | 522 | 20 | 66 | 9.1 | −5.9 | −3.7 | 298 | 286 | 350 |
| Ex. 8 | 1h | 531 | 545 | 25 | 44 | 12.8 | −5.85 | −3.7 | 191 | 300 | 363 |
| Ex. 9 | 1i | 508 | 525 | 20 | 38 | 11.5 | −6.1 | −3.8 | 246 | 315.9 | 368 |
| Ex. 10 | 1j | 547 | 570 | 79 | 127 | 8.7 | −5.8 | −4.1 | 226 | 333 | 375 |
| Ex. 11 | 1k | 527 | | 26 | | 15.3 | | | N.D. | 380 | 382 |
| Comp. | 1l | 526 | 541 | 25 | 129 | 3.5 | −5.9 | −3.7 | 172 | 193.9 | 254 |
| Ex. 1 | | | | | | | | | | | |
| Comp. | 1m | 527 | 539 | 25 | 54 | 11.1 | −5.9 | −3.7 | 285 | 289 | |
| Ex. 2 | | | | | | | | | | | |

For the evaluation of Table 1, the absorbance properties of compounds 1a to lm were evaluated in a solution state and in a thin film state.

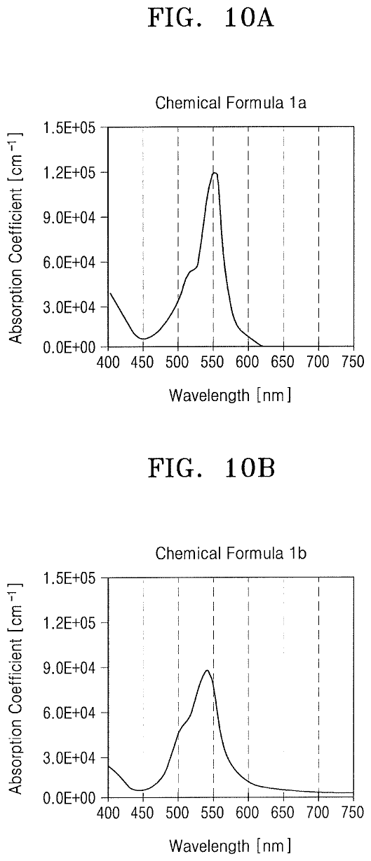

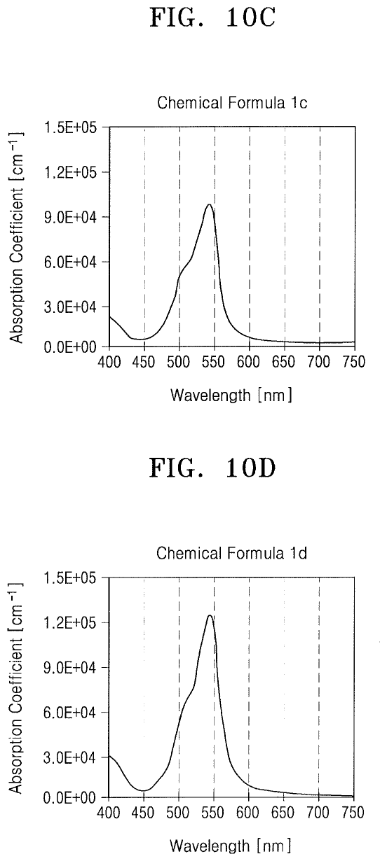

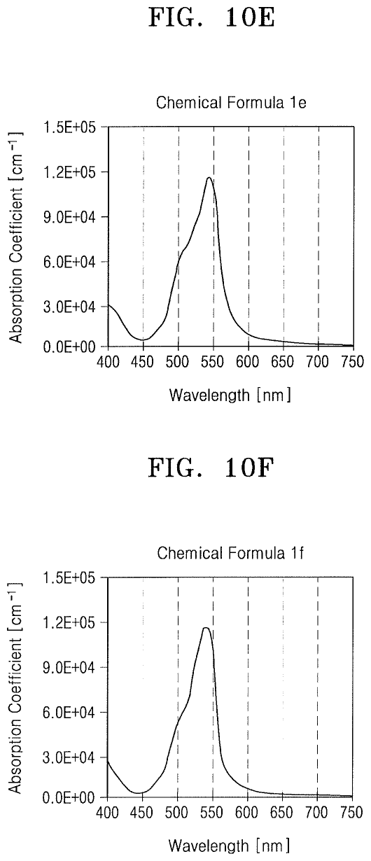

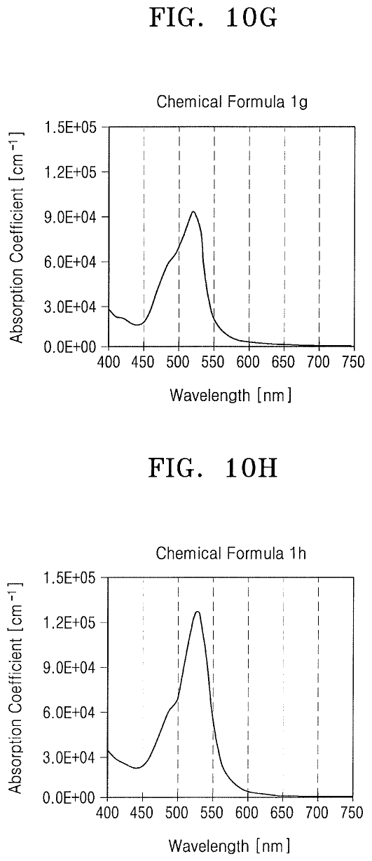

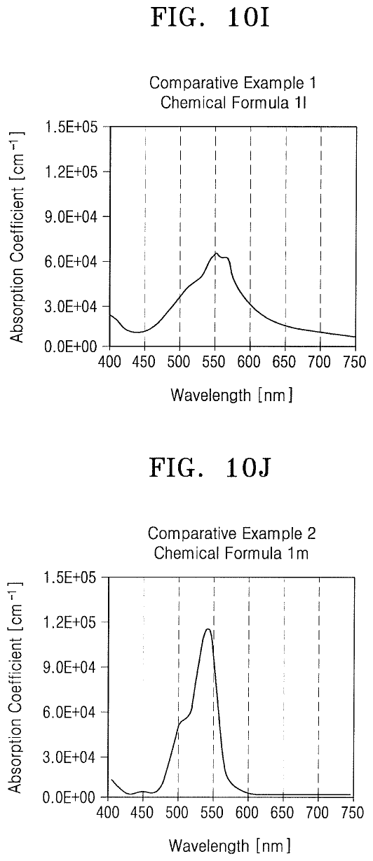

FIGS. 10A to 10H illustrate absorption curve graphs of the absorption properties of compounds of Examples 1 to 8, i.e., compounds of Chemical Formulas 1a to 1h, which absorb light of an ultraviolet (UV)-visible range, and FIGS. 10I and 10J illustrate absorption curve graphs of the absorption properties of compounds of Comparison Examples 1 and 2, i.e., compounds of Chemical Formulas 1l and 1m.

In the results of Table 1, each of the compounds of Chemical Formulas 1a to 1h had a wavelength of maximum absorption λ max of 522 nm to 545 nm and an FWHM of 44 nm to 74 nm in a thin film state. For example, each of the compounds of Chemical Formulae 1a to if had a wavelength of maximum absorption λ max of 537 nm to 542 nm and an FWHM of 52 nm to 74 nm in a thin film state. From these results, it may be seen that a thin film including the compounds of Chemical Formulae 1a to 1h may provide excellent selective absorption of light of a green wavelength region.

Also, from the results of FIGS. 10a to 10h, it may be seen that the absorption curves of the compounds of Chemical Formulas 1a to 1h are similar to the Gaussian distribution.

Also, Table 1 shows the results of measuring a transition temperature Tm, a sublimation temperature Ts, and a thermal degradation temperature Td of each of the compounds of Chemical Formulas 1a to 1m in order to evaluate the thermal stability of the compounds of Chemical Formulas 1a to 1m. In Table 1, the transition temperatures Tm of the compounds of Chemical Formulas 1a to 1h were generally high enough and the thermal degradation temperatures Td of the compounds of Chemical Formulas 1a to 1h were sufficiently higher than the sublimation temperatures Ts. From these results, it may be seen that the compounds of Chemical Formulas 1a to 1h may be very stable under vacuum.

The compound of Chemical Formula 1l according to Comparison Example 1 exhibited a relatively wide FWHM and a relatively poor thermal property in a thin film state and exhibited a relatively high reflectance in a thin film state. Also, the compound of Chemical Formula 1l according to Comparison Example 1 exhibited absorption properties not only in a green wavelength region but also in a blue wavelength region and a red wavelength region. This may be because the transition temperature Tm was relatively low under vacuum and thus it may exist as relatively large aggregate particles. The compound of Chemical Formula 1k according to Example 11 was decomposed in an evaluation process and was impossible to deposit under vacuum, and thus, the sublimation temperature Ts and the decomposition temperature Td were very close to each other.

### Device Manufacturing Example 1 (Manufacturing of Organic Photoelectric Device)

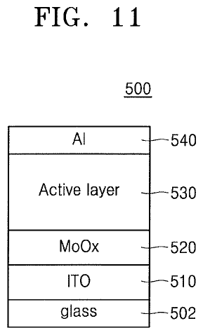

FIG. 11 illustrates a cross-sectional view of examples of manufacturing an organic photoelectric device, according to embodiments.

Referring to FIG. 11, a first electrode layer 510 including ITO was formed on a glass substrate 502, and an electron blocking layer 520 including a molybdenum oxide thin film having a thickness of 30 nm was formed on the first electrode layer 510. Thereafter, the compound of Chemical Formula 1a and C60 (Frontier Carbon Company Ltd.) were co-deposited on the electron blocking layer 520 at a volume ratio of 3:2 to form an active layer 530 having a thickness of 80 nm. Thereafter, Al was vacuum-deposited on the active layer 530 to form a second electrode 540 having a thickness of 100 nm, thereby manufacturing an organic photoelectric device 500.

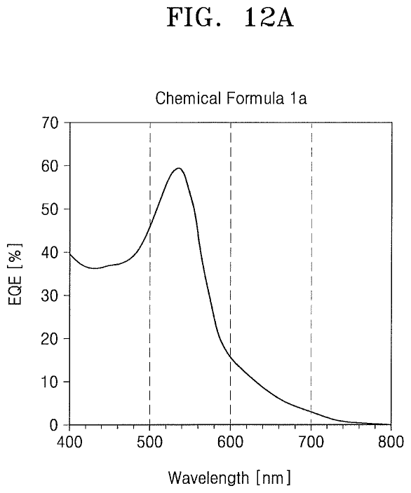

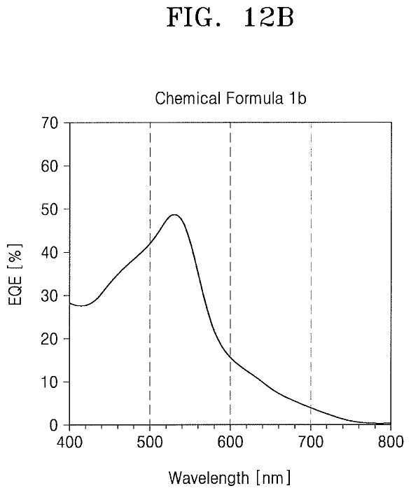

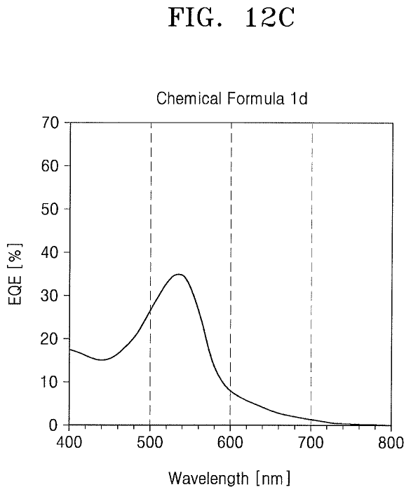

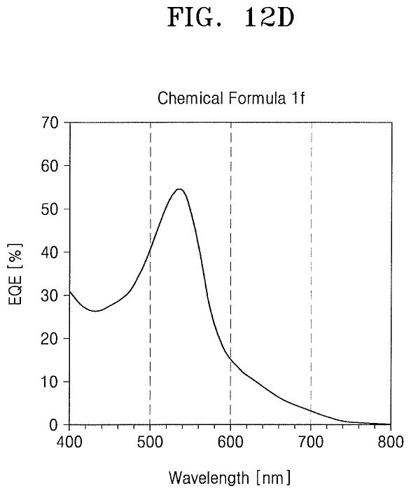

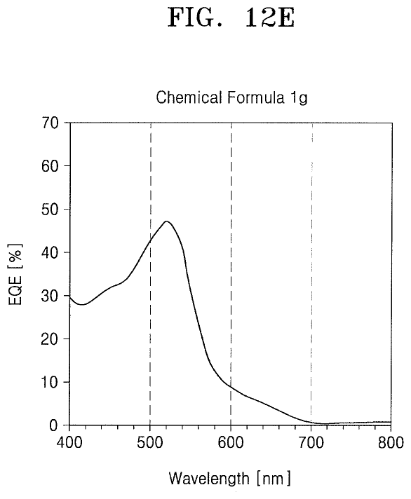

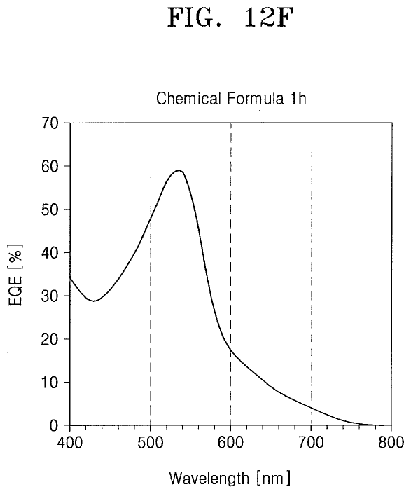

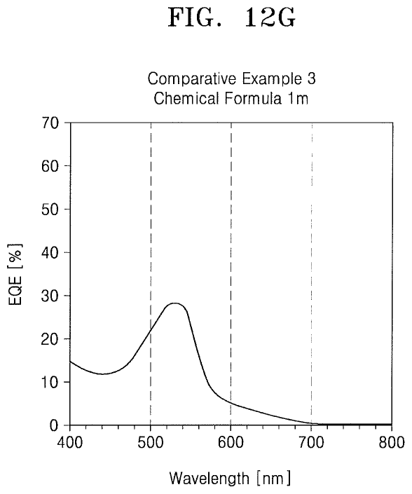

FIG. 12A illustrates a graph of the results of evaluating the EQE depending on the wavelength of the organic photoelectric device 500 described with reference to FIG. 11.

The EQE was measured by using the Incident Photo to Charge Carrier Efficiency (IPCE) measurement system (CEP-2000M, Bunkoukeiki, Japan).

### Device Manufacturing Examples 2 through 6 (Manufacturing of Organic Photoelectric Devices)

Organic photoelectric devices were manufactured in the same way as in Device Manufacturing Example 1 except that compounds of Chemical Formula 1b, Chemical Formula 1d, Chemical Formula 1f, Chemical Formula 1g, and Chemical Formula 1h were used instead of the compound of Chemical Formula 1a.

FIGS. 12B to 12F illustrate graphs of the results of evaluating the EQE depending on the wavelengths of organic photoelectric devices having active layers including the compounds of Chemical Formulas 1b, 1d, 1f, 1g, and 1h.

### Comparison Example 3 (Manufacturing of Organic Photoelectric Device)

An organic photoelectric device was manufactured in the same way as in Device Manufacturing Example 1 except that a compound of Chemical Formula 1m was used instead of the compound of Chemical Formula 1a.

FIG. 12G illustrates a graph of the results of evaluating the EQE depending on the wavelength of an organic photoelectric device having an active layer including the compound of Chemical Formula 1m.

From the results of FIGS. 12A to 12G, it may be seen that the organic photoelectric devices having an active layer including compounds of Chemical Formula 1a, Chemical Formula 1b, Chemical Formula 1d, Chemical Formula 1f, Chemical Formula 1g, and Chemical Formula 1h, had a relatively high EQE in a green wavelength range of about 500 nm to about 570 nm, and the EQE in a blue wavelength range of about 400 to about 450 nm and the EQE in a red wavelength range of about 600 nm or more was lower than the EQE in the green wavelength region.

In the case of the organic photoelectric device according to Comparison Example 3, which included the compound of Chemical Formula 1m that has two phenylene rings and one phenyl ring at the meso position of a BODIPY core and does not include a sulfur atom, from the results of Table 1, although it exhibited similar physical properties to compounds of Chemical Formula 1a, Chemical Formula 1b, Chemical Formula 1d, Chemical Formula 1f, Chemical Formula 1g, and Chemical Formula 1h, it had a lower EQE in the green wavelength region than the organic photoelectric devices having an active layer including compounds of Chemical Formula 1a, Chemical Formula 1b, Chemical Formula 1d, Chemical Formula 1f, Chemical Formula 1g, and Chemical Formula 1h.

### Thermal Stability Evaluation

It may be seen that the properties of the organic photoelectric devices having an active layer including compounds of Chemical Formula 1a, Chemical Formula 1b, Chemical Formula 1d, Chemical Formula 1f, Chemical Formula 1g, and Chemical Formula 1h were not degraded even after annealing at 130° C. under an N₂ gas atmosphere. From these results, it may be seen that compounds of Chemical Formula 1a, Chemical Formula 1b, Chemical Formula 1d, Chemical Formula 1f, Chemical Formula 1g, and Chemical Formula 1h provided excellent thermal stability.

It may be seen that the properties of the organic photoelectric device having an active layer including a compound of Chemical Formula 1l were degraded after annealing at 130° C. under an N₂ gas atmosphere. This may be attributed to the fact that the thermal stability of a structure of Chemical Formula 1l may be lowered in the form of a thin film.

One or more embodiments may provide an organic compound capable of selectively absorbing light of a green wavelength region. One or more embodiments may provide an organic compound that may have excellent thermal stability and carrier mobility and may selectively absorb light of a green wavelength region. One or more embodiments may provide an organic photoelectric device that may exhibit high external quantum efficiency (EQE) by including an organic compound that may have excellent thermal stability and carrier mobility and may selectively absorb light of a green wavelength region. One or more embodiments may provide an image sensor including an organic photoelectric device with improved EQE. One or more embodiments may provide an electronic device including an organic photoelectric device with improved EQE. One or more embodiments may provide a compound that provides a thin film structure in which molecules are densely packed.

One or more embodiments may provide a fused cyclic thiophene structure having sulfur atoms in which carrier mobility, and in turn quantum efficiency, may be improved by superposition of p orbitals of sulfur atoms having a large atomic radius.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1.-20. (canceled)

21. An organic photoelectric device, comprising:
a first electrode and a second electrode facing each other; and
an active layer between the first electrode and the second electrode,
wherein the active layer includes an organic compound represented by Chemical Formula 1, 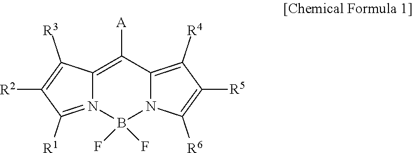
wherein, in Chemical Formula 1,
R¹, R², R³, R⁴, R⁵, and R⁶ are each independently a hydrogen atom, a substituted or unsubstituted C1-C4 alkyl group, a substituted or unsubstituted C1-C4 alkoxy group, or a substituted or unsubstituted C1-C4 alkylthio group, and
A is a functional group including a heteroaryl group that includes at least one sulfur atom.

22. The organic photoelectric device as claimed in claim 21, wherein the active layer further includes an n-type semiconductor compound.

23. The organic photoelectric device as claimed in claim 21, wherein the active layer further includes an n-type semiconductor compound that includes a fullerene compound.

24. The organic photoelectric device as claimed in claim 21, wherein, in the organic compound represented by Chemical Formula 1, A includes at least three ring structures and at least one ring structure of the at least three ring structures includes a thiophene moiety.

25. The organic photoelectric device as claimed in claim 21, wherein, in the organic compound represented by Chemical Formula 1, A includes a monocyclic ring moiety or a polycyclic ring moiety, the monocyclic ring moiety or polycyclic ring moiety including at least one thiophene moiety.

26. The organic photoelectric device as claimed in claim 21, wherein, in the organic compound represented by Chemical Formula 1, A has a structure represented by Chemical Formula 2: 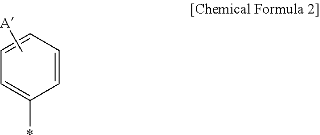
wherein, in Chemical Formula 2,
A′ is a functional group having a heteroaryl group that includes at least one sulfur atom, and
“*” is a bonding position.

27. The organic photoelectric device as claimed in claim 26, wherein, in Chemical Formula 2, A′ includes a monocyclic ring moiety or a polycyclic ring moiety, the monocyclic ring moiety or polycyclic ring moiety including at least one thiophene moiety.

28. The organic photoelectric device as claimed in claim 21, wherein A has a structure represented by Chemical Formula 3: 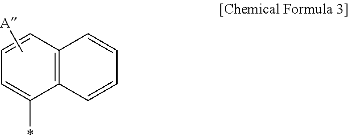
wherein, in Chemical Formula 3,
A″ is a functional group having a heteroaryl group that includes at least one sulfur atom, and
“*” is a bonding position.

29. The organic photoelectric device as claimed in claim 28, wherein, in Chemical Formula 3, A″ includes a monocyclic ring moiety or a polycyclic ring moiety, the monocyclic ring moiety or polycyclic ring moiety including at least one thiophene moiety.

30. The organic photoelectric device as claimed in claim 21, wherein, in the organic compound represented by Chemical Formula 1, A is a group represented by one of the following formulae, 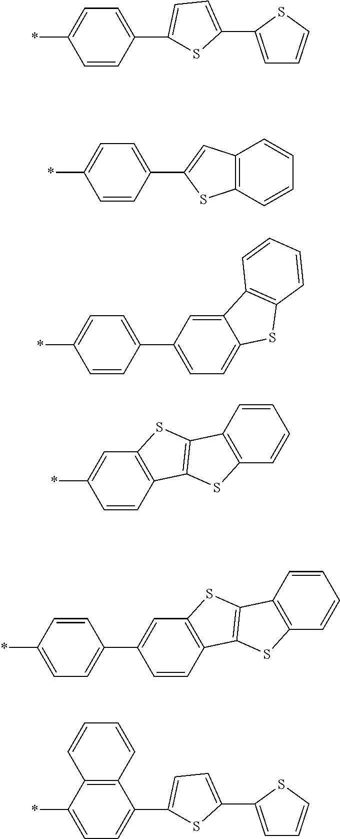
wherein, in the above formulae, “*” is a bonding position.

31. The organic photoelectric device as claimed in claim 21, wherein, in the organic compound represented by Chemical Formula 1:
R¹, R³, R⁴, and R⁶ are each independently a C1-C3 alkyl group, and
R² and R⁵ are each independently a hydrogen atom or a C1-C3 alkyl group.

32. An image sensor comprising the organic photoelectric device as claimed in claim 21.

33. An image sensor, comprising:
a semiconductor substrate; and
an organic photoelectric device on the semiconductor substrate,
wherein the organic photoelectric device includes:
a first electrode and a second electrode facing each other; and
an active layer between the first electrode and the second electrode, the active layer including an organic compound represented by Chemical Formula 1, 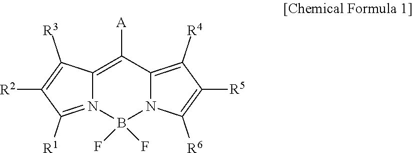
wherein, in Chemical Formula 1, R¹, R², R³, R⁴, R⁵, and R⁶ are each independently a hydrogen atom, a substituted or unsubstituted C1-C4 alkyl group, a substituted or unsubstituted C1-C4 alkoxy group, or a substituted or unsubstituted C1-C4 alkylthio group, and
A is a functional group including a heteroaryl group that includes at least one sulfur atom.

34. The image sensor as claimed in claim 33, wherein:
R¹, R³, R⁴, and R⁶ are each independently a C1-C3 alkyl group,
R² and R⁵ are each independently a hydrogen atom or a C1-C3 alkyl group, and
A has a structure represented by Chemical Formula 2 or Chemical Formula 3: 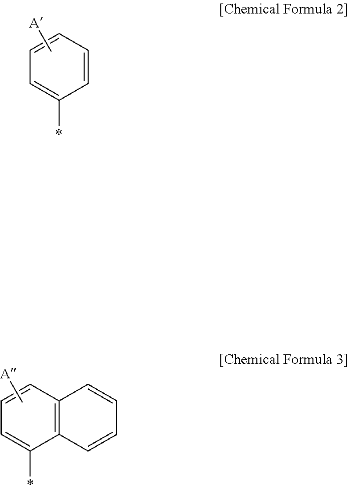
wherein, in Chemical Formula 2 and Chemical Formula 3,
A′ and A″ are each a functional group having a heteroaryl group that includes at least one sulfur atom, and
“*” is a bonding position.

35. The image sensor as claimed in claim 33, wherein, in the organic compound represented by Chemical Formula 1, A is a group represented by one of the following formulae, 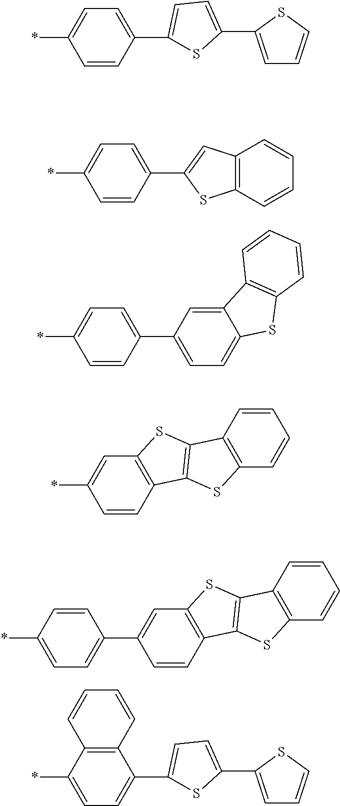
wherein, in the above formulae, “*” is a bonding position.

36. The image sensor as claimed in claim 33, wherein the active layer further includes an n-type semiconductor compound that includes a fullerene compound.

37. The image sensor as claimed in claim 33, further comprising:
a first photo-sensing device integrated in the semiconductor substrate to sense light of a blue wavelength region; and
a second photo-sensing device integrated in the semiconductor substrate to sense light of a red wavelength region,
wherein the organic photoelectric device is to selectively absorb light of a green wavelength region.

38. The image sensor as claimed in claim 33, further comprising a color filter layer between the semiconductor substrate and the organic photoelectric device,
wherein the color filter layer includes:
a blue color filter to selectively transmit light of a blue wavelength region; and
a red color filter to selectively transmit light of a red wavelength region.

39. The image sensor as claimed in claim 33, further comprising:
a first photo-sensing device integrated in the semiconductor substrate to sense light of a blue wavelength region; and
a second photo-sensing device integrated in the semiconductor substrate to sense light of a red wavelength region,
wherein the first photo-sensing device, the second photo-sensing device, and the organic photoelectric device overlap each other in a vertical direction.

40. An electronic device comprising the image sensor as claimed in claim 33.
